(19) United States
(12) Patent Application Publication
(10) Pub. No.: US 2025/0334877 A1
(43) Pub. Date: Oct. 30, 2025

(54) PEROXIDE-STABILIZED ORGANOTIN PHOTORESIST COMPOSITIONS AND PATTERNING

(71) Applicant: Inpria Corporation, Corvallis, OR (US)

(72) Inventors: Jordan Boutilier, Philomath, OR (US); Deok Hie Park, Corvallis, OR (US); Kai Jiang, Corvallis, OR (US); Brian J. Cardineau, Corvallis, OR (US); Munendra Yadav, Corvallis, OR (US); Alan J. Telecky, Albany, OR (US)

(21) Appl. No.: 19/188,103

(22) Filed: Apr. 24, 2025

Related U.S. Application Data
(60) Provisional application No. 63/638,615, filed on Apr. 25, 2024.

(51) Int. Cl. G03F 7/004

(52) U.S. Cl. CPC G03F 7/0043

(57) ABSTRACT

Organometallic precursor solutions containing one or more peroxide compositions, such as hydrogen peroxide, urea hydrogen peroxide, and organo peroxydisulfates, are described. Corresponding coated substrates and radiation patterned substrates as well as methods of preparing organometallic precursor solutions containing a peroxide composition are also described. Novel organo peroxydisulfates and a technique for synthesizing an organo peroxydisulfate are further described. The incorporation of a peroxide composition into an organometallic photoresist composition is described as a way to increase stability of organometallic precursor solutions and/or to improve the patterning performance of organometallic photoresist coatings.

### CROSS REFERENCE TO RELATED APPLICATIONS

This application claims priority to copending provisional application 63/638,615 to Boutillier et al., entitled “PEROXIDE-STABILIZED ORGANOTIN PHOTORESIST COMPOSITIONS AND PATTERNING”, filed Apr. 25, 2024, incorporated herein by reference.

### FIELD OF THE INVENTION

The invention relates to organometallic, in particular organotin, patterning compositions comprising peroxide compound additives. Specifically, the peroxide compound can stabilize an organotin precursor solution and inhibit precipitation of the organotin composition. During patterning, the peroxide compound can undergo a photosensitive mechanism that can produce species which can participate in chemistry to provide additional routes of contrast generation and/or enhance the EUV sensitivity of the photoresist coating.

### BACKGROUND

Organometallic compounds provide ligated metal ions in solution and vapor forms for deposition of thin films. Organotin compounds provide high EUV absorption and radiation sensitive tin-ligand bonds that can be used to lithographically pattern thin films. The manufacture of semiconductor devices at ever shrinking dimensions with EUV radiation requires new materials with wide process latitude to achieve required patterning resolutions and low defect densities.

### SUMMARY OF THE INVENTION

In a first aspect, the invention pertains to an organotin precursor solution comprising a mixture of an organic solvent, a first organotin composition represented by the formula RₙSnX₄₋ₙ where n=1, 2 or 3, R is an organo group with 1 to 31 carbon atoms and X is a hydrolysable ligand, and a peroxide composition.

In another aspect, the invention pertains to a method of preparing an organotin precursor solution. The method comprises combining an organic solvent, a peroxide composition and a first organo tin composition represented by the formula RₙSnX₄₋ₙ where n=1, 2 or 3, R is an organo group with 1 to 31 carbon atoms and X is a hydrolysable ligand.

In another aspect, the invention pertains to a coated substrate comprising a substrate with a surface and a layer on the surface comprising organo tin moieties, an oxo-hydroxo network, and a peroxide composition.

In another aspect, the invention pertains to a patterned substrate comprising a substrate with a patterned layer with an unirradiated region comprising organo tin moieties, an oxo-hydroxo network and a peroxide composition, and an irradiated region having an enhanced oxo-hydroxo network with at least some tin atoms fragmented from organo groups and at least some peroxide composition not persisting.

In another aspect, the invention pertains to a method for forming a patterned substrate comprising a substrate with a patterned layer with an unirradiated region comprising organo tin moieties, an oxo-hydroxo network and a peroxide composition, and an irradiated region having an enhanced oxo-hydroxo network with at least some tin atoms fragmented from organo groups and at least some peroxide composition not persisting. The method comprises irradiating a coated substrate comprising a substrate with a surface and a layer on the surface comprising organo tin moieties, an oxo-hydroxo network, and a peroxide composition with patterned radiation.

In other aspects, the invention pertains to an organo peroxydisulfate represented by the formula:

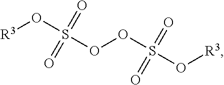

where R³ is an organo group with 1 to 15 carbon atoms, with optional unsaturated groups, optional aromatic groups, and combinations thereof.

In additional aspects, the invention pertains to a method for synthesizing an organo peroxydisulfate comprising reacting a mixture of an organohalide, R³X, and a peroxydisulfate anion, wherein R³ is an organo group with 1 to 15 carbon atoms, with optional unsaturated groups, optional aromatic groups, or a combination thereof, and X is a halogen.

### BRIEF DESCRIPTION OF THE DRAWINGS

FIG. 1 is a cartoon depicting the patterning of a peroxide-enhanced organotin coating.

FIG. 2 shows a set of CD-SEM micrographs for six patterned organotin coatings formed with a peroxide-enhanced precursor solution (F) or with a precursor solution without peroxide enhancement (E) and irradiated with the indicated EUV dose and baked at the indicated PEB temperature. The three values associated with each image indicate radiation dose, critical dimension, and line width roughness from left to right.

FIG. 3 is a plot of the critical dimension of line space patterns, as determined by CD-SEM, as a function of EUV radiation dose in a dose meander experiment for an organotin coating formed with a peroxide-enhanced precursor solution (indicated by solid circle marker) and an organotin coating formed with a precursor solution without peroxide enhancement (indicated by empty circle marker). Both coatings were subjected to a PEB temperature of 200° C.

FIG. 4 is a plot of the critical dimension of line space patterns, as determined by CD-SEM, as a function of EUV radiation dose in a dose meander experiment for an organotin coating formed with a peroxide-enhanced precursor solution (indicated by solid circle marker) and an organotin coating formed with a precursor solution without peroxide enhancement (indicated by empty circle marker)). Both coatings were subjected to a PEB temperature of 210° C.

FIG. 5 is a plot of the critical dimension of line space patterns, as determined by CD-SEM, as a function of EUV radiation dose in a dose meander experiment for an organotin coating formed with a peroxide-enhanced precursor solution (indicated by solid circle marker) and an organotin coating formed with a precursor solution without peroxide enhancement (indicated by empty circle marker). Both coatings were subjected to a PEB temperature of 220° C.

FIG. 6 is a ¹H NMR spectrum of O,O-bis ethylphenyl peroxydisfulate.

FIG. 7 is a ¹³C NMR spectrum of O,O-bis ethylphenyl peroxydisulfate.

### DETAILED DESCRIPTION OF THE INVENTION

The addition of peroxide compounds to organotin photoresist compositions can improve the solution stability and radiation sensitivity of the photoresist compositions. In some embodiments, peroxide compounds can coordinate and/or react with the organotin species in the solution to form peroxide ligands that can hinder the metal hydrolysis/condensation reactions that can lead to insoluble precipitates. In some embodiments, peroxide compounds can associate with the organo tin moieties in a deposited material and/or in solution to facilitate the patterning process, such as lowering effective radiation dose. The results herein suggest that the solubility of organotin oxo hydroxo species (i.e., clusters) can be improved by the incorporation of peroxide ligands or possibly other interactions with peroxide compounds, which improves precursor stability with respect to water. While the organotin compositions of particular interest have organic ligands bound to tin (Sn⁴⁺) with a C—Sn bond and hydrolysable, but otherwise relatively stable, ligands, some uncontrolled contamination with water can result in formation of organotin oxo-hydroxo species, which may destabilize the precursor solution with respect to precipitation. The presence of peroxides can stabilize the precursor solutions against precipitation. Furthermore, patterning doses can be reduced through the addition of peroxide compounds to the organotin photoresist compositions without significantly compromising patterning performance. Thus, the inclusion of the peroxides can provide precursor stability and patterning advantages. Desirable bis-organo peroxydisulfate compounds are described that are promising peroxide compounds for lowering radiation doses for effective patterning. Appropriate synthesis procedures for synthesizing the bis-organo peroxydisulfate compounds are described and exemplified.

Organotin compounds of interest generally are represented by the formula RₙSnL₄₋ₙ, where n=1, 2 or 3, R is an organo group described further below, and L is a hydrolysable group. Blends of these compounds can be effectively used in the ultimate patterning composition, and blends of compounds with different R groups are exemplified. Generally, L can be any reasonable hydrolysable ligand, and in particular can be independently an alkoxide (—OR′), a dialkylamide (—NR′₂), an alkylacetylide (—C≡CR′), an alkylsilylamide (—N(SiR′₃)₂), or a combination thereof, wherein R′ generally is an organo group with 1 to 10 carbon atoms, optional unsaturated groups, and optional heteroatoms. Commercial photoresist development has focused on the mono-organo compounds with n=1, but the beneficial effects of the peroxide additive can also apply for compounds with n=2 and n=3. Blends of compounds with different values of n, with or without the same R group and/or the same L group, can be used if desired.

Based on a majority of commercial photoresist development efforts, monoalkyltin trialkoxide (RSn(OR′)₃) and monoalkyltin triamide (RSn(NR′₂)₃) precursor compounds, are useful compositions for extreme ultraviolet (EUV) lithography. Organotin compounds can also be referred to as alkyltin compounds or hydrocarbyltin, and the three terms are used interchangeably herein and generally in the art. The use of alkyltin compounds in high performance radiation-based patterning compositions is described, for example, in U.S. Pat. No. 9,310,684 to Meyers et al., entitled “Organometallic Solution Based High Resolution Patterning Compositions,” incorporated herein by reference. Refinements of these organometallic compositions for patterning are described in U.S. Pat. No. 10,642,153 to Meyers et al., entitled “Organometallic Solution Based High Resolution Patterning Compositions and Corresponding Methods,” and 10,228,618 to Meyers et al. (hereinafter the '618 patent), entitled “Organotin Oxide Hydroxide Patterning Compositions, Precursors, and Patterning,” both of which are incorporated herein by reference.

The organotin precursor compositions comprise a ligand that forms a carbon—tin bond (C—Sn) that is sensitive to irradiation. To form stable precursors solutions for commercial applications, desirable organotin precursors compositions comprise ligands that can be hydrolyzed with water or other suitable reagent under appropriate conditions to form alkyl tin oxo-hydroxo patterning compositions, which, when fully hydrolyzed, can be represented by the formula RₙSnO_{(1.5-(x/2-(n/2))}(OH)ₓ, n=1, 2 or 3, and 0<x<3, which reduces for n=1 to RSnO_{(1.5-(x/2))}(OH)ₓ where 0<x<3. It can be convenient to perform the hydrolysis to form the oxo-hydroxo compositions in situ, such as during deposition and/or following initial coating formation. Monoalkyl tin precursor compositions can generally be represented by the formula RSnL₃, where R is an alkyl group having a radiation-sensitive Sn—C bond and from about 1 to about 31 carbons atoms, optionally substituted, for example, with a cyano, thio, silyl, ether, keto, ester, or halogenated functional group or a combination thereof and L is a hydrolysable ligand. For processing to form radiation patternable coatings, L is generally hydrolysed before or during (e.g., in-situ) deposition to result in a coating comprising a polymeric organotin oxo-hydroxo composition on a substrate wherein the Sn—R bonds remain substantially intact. As a result, a radiation patternable coating having radiation-sensitive Sn—R bonds can be realized.

Processing of the organotin precursor compositions to afford organotin oxo-hydroxo coatings generally involves hydrolysis of the RₙSnL₄₋ₙ(n=1, 2, or 3) composition(s) to afford the related organotin oxohydroxo composition(s). Hydrolysis can be performed prior to the deposition process to yield soluble organotin oxo-hydroxo species (i.e., clusters, oligomeric species, etc.) These soluble organotin oxo-hydroxo species can then be dissolved and/or dispersed into a suitable solvent to form an organotin photoresist solution that can then be used to form radiation-patternable organotin oxo-hydroxo coatings. Alternatively, the organotin precursor compositions can be directly dissolved in a suitable solvent to form a photoresist solution that can then be used to form radiation-patternable organotin oxo-hydroxo coatings. The organotin precursor compositions can also be hydrolysed in-situ with water during the substrate coating process, such as during vapor deposition. Various processing options are described further in the '684 and '618 patents referenced above. Commercial organotin photoresists rely on in situ hydrolysis, and precursors with hydrolysable ligands can provide appropriate shelf-life and desirable patterning performance. Further discussion below focuses on the in situ hydrolyzed precursor compositions. Further discussion also focuses on the mono-organotin compositions, but the discussion can be readily generalized for n=2 and n=3 embodiments.

Applicant identified the potential of peroxide stabilizing ligands to facilitate patterning with metal-based resists in early work promising work. See, U.S. Pat. No. 9,176,377 to Stowers et al. (hereinafter the '377 patent), entitled “Patterned Inorganic Layers, Radiation Based Patterning Compositions and Corresponding Methods,” incorporated herein by reference. While these patterning compositions yielded excellent results, these compositions proved problematic with respect to achieving viable commercial products. Work from IBM attempted to overcome the difficulties from the materials in the '377 patent using compounds with tantalum metal ions, but without apparently success since there is no evidence of commercialization. See U.S. patent application 2013/0224652 to Bass et al., entitled “Metal Peroxo Compounds With Organic Co-Ligands for Electron Beam, Deep UV, and Extreme UV Photoresist Applications”, incorporated herein by reference. The work herein discovers appropriate conditions to supplement existing effective organometallic pattering compositions with further improvements available from inclusion of peroxides. In contrast with this earlier work, the present precursor compositions are based on organic solvent rather than aqueous solvent.

For organotin photoresist compositions wherein the organotin precursor(s) are dissolved into a solvent for spin-coating or similar solution-based deposition methods, organotin trialkoxides (RSnL₃, L=OR′) can be desirable for use. Some advantages to organotin trialkoxide compositions are, for example, the production of benign side-products, e.g., alcohols, that are relatively innocuous compared to the production of other reaction products (e.g., amines) which may cause contamination concerns, environmental health and safety concerns, and/or similar issues within the wafer track and/or wafer fab. While organotin triamides can be useful as precursors in vapor-based deposition methods (such as described in the '618 patent), organotin trialkoxides also possess appreciable vapor pressures and low melting points which also makes them attractive compounds for use in vapor deposition methods to prepare radiation-patternable coatings. In any case, the choice of organotin precursors used to produce radiation-patternable organotin oxide hydroxide films can be largely driven by processing considerations and/or limitations.

The high hydrolytic sensitivity of many organotin compounds, such as the RSnL₃ compositions described above, is advantageous for the formation of radiation-sensitive organotin oxide hydroxide films. Though some hydrolysis/condensation can occur within the solutions prior to deposition and formation of the organotin oxide hydroxide films, it is generally undesirable for uncontrolled hydrolysis of the RSnL₃ to occur prior to deposition. Uncontrolled exposure of the organotin photoresist solutions to water can lead to gelation and/or hydrolysis/condensation products with low solubility, such as high nuclearity clusters or particles. The solubility of these organotin hydrolysis/condensation products generally depends on the degree of hydrolysis/condensation that occurs, and which generally corresponds to the amount of water introduced to the organotin composition. As more water is introduced to and reacted with the solubilized organotin compositions, the extent of hydrolysis/condensation generally increases which results in an increase in number of and/or higher nuclearity hydrolysis/condensation products. The hydrolysis/condensation products can then agglomerate or condense to form less soluble species that can precipitate out of the solution during storage or while installed on a wafer track.

Water can be inadvertently introduced to the organotin photoresist solutions through various routes during use and handling. The organic solvents used to formulate organotin photoresist solutions, such as alcohols, ketones, ethers, and esters, can absorb water over time from the atmosphere when exposed to ambient or humid air. Materials of construction with which the photoresist is processed, handled, and transferred, such as through tubing, lines, tanks and so forth, can possess a non-zero permeability to moisture which can lead to an increase in water content of the organic solvent solutions contained within an otherwise fully or substantially sealed (i.e., closed to ambient atmosphere) environment or system. The absorbed water can result in uncontrolled hydrolysis/condensation processes within the organotin photoresist solution that can lead to gelation and the formation of precipitates. Precipitation of photoresist solutions is generally undesirable for a variety of reasons, for example contamination of wafer fab equipment, line clogging, the formation of film and patterning defects, and variable processing results due to changes in solution concentration or speciation. It is therefore desirable to mitigate the formation of precipitates and high nuclearity clusters due to uncontrolled hydrolysis/condensation.

Due to the potential complication of water management in the organotin resists solutions, more reliable results have been obtained through the direct management of the water content in the initially formulated resists. Specifically, it has been found that controlling the water level can result in consistent and stable precursor solutions. In particular, the water level can be adjusted, generally by addition of small amounts of water to the solvent. to achieve the target water levels, generally no more than about 10,000 ppm by weight, and in additional embodiments from about 200 ppm by weight to about 5000 ppm by weight, 250 ppm by weight to 3000 ppm by weight, or 300 ppm by weight to 1500 ppm by weight. A person of ordinary skill in the art will recognize that additional ranges within the explicit ranges above are contemplated and are within the present disclosure. The use of water content adjustment is discussed further in U.S. Pat. No. 11,300,876 (herein the '876 patent) to Jiang et al., entitled “Stable Solutions of Monoalkyl Tin Alkoxides and Their Hydrolysis and Condensation Products,” incorporated herein by reference. If additional water is provided with the peroxide additive, this added water can be considered appropriately in the total precursor solution formulation, although as described herein, peroxides provided improved precursor stability suggesting reduced water sensitivity. Nevertheless, controlling water in the precursor solution using approaches that have been developed, as potentially adjusted for peroxide addition, is a desirable goal to achieve consistent patterning results.

While not wanting to be limited by theory, it is believed that the nuclearity of tin clusters hydrolyzed in solution prior to deposition can correlate to the size of clusters further formed during deposition. Patternable coatings comprising high nuclearity clusters can limit the smallest feature size that can be repeatedly produced without defects. In this way, the organotin clusters can be likened to pixels in a digital image, such that larger pixels reduce the overall resolution and detail of an image. As the feature size approaches the dimensions of larger organotin clusters or agglomerated species, defects may become more prevalent, leading to degradation in film quality, pattern fidelity, and resolution. It can be desirable to prevent or limit hydrolysis of the precursor composition prior to deposition in order to realize a deposited patternable coating with smaller average cluster sizes. Results presented herein suggest that the presence of the peroxide composition can alter the cluster formation pathways for a particular amount of water relative to solutions that do not comprise peroxide compositions. Potentially similar degrees of hydrolysis may occur, although ligated peroxide could inhibit hydrolysis and thereby inhibit the formation of larger clusters.

Peroxide-based compositions, at least some of which may form ligands to the tin, can stabilize the organotin composition against uncontrolled hydrolysis/condensation processes that lead to gelation and insoluble precipitates. By adding peroxide compounds to the organotin photoresist composition, solutions having improved stability can be formed that show improved resistance to the formation of precipitates in the presence of water. Peroxide compounds can be incorporated into organotin compositions that exhibit improved solubilities compared to non-peroxide containing compositions. As shown in the examples herein, organotin solutions comprising peroxide can remain precipitate-free at high water content compared to non-peroxide solutions at similar water content. The organotin compositions have 4 ligands to the tin(+4) atom forming a neutral species, but the tin can further accept one or two more neutral ligands to form a pyramidal or octahedral structure, in which solvent molecules, water, or peroxide compounds may participate as neutral ligands and compete for binding sites. Alternatively, a peroxide, such as hydrogen peroxide, could hydrolyze a hydrolysable ligand, such as an alkoxide ligand, to form a ligand to the tin, such as an OOH⁻ bound as Sn—OOH.

The presence of peroxide can stabilize organotin precursor solutions comprising an organotin composition and an organic solvent. Particularly, when the precursor solution comprises a secondary alcohol solvent, for example 4-methyl 2-pentanol, undesirable reactions can occur between the alcohol and atmospheric species such as oxygen (O₂). While not wanting to be limited by theory, it is believed that secondary alcohols can undergo autooxidation to form ketones and reactive peroxide species as products. In and of itself, the presence of reactive peroxide species is not undesirable, but rather the uncontrolled nature of their formation. Variation in peroxide species concentration can increase patterning variability between batches due to factors including but not limited to changes in processing environment composition and inconsistent hold-up times between processing steps. Variability between batches can be detrimental to the lithographic process, as the small feature size and high feature density means minor variations in patterning performance can render integrated circuit devices inoperable. Since primary alcohol solvents are less prone to autooxidation, the use of primary alcohols as a component of the solvent can reduce the incidence of inadvertent peroxide generation, which can result in inconsistent patterning results.

While the addition of peroxide additives is found to provide stability, it has also been found that formation of radicals in the precursors or in materials during patterning can result in precursor instability and/or degradation of patterning performance. To decrease deleterious effects from radicals, further additives can be included in the precursor solutions to scavenge radicals. Such additives have been shown to be beneficial, as described in copending U.S. patent application Ser. No. 19/042,239 to Eberle et al. (hereinafter the '239 application), entitled “Radical Scavenger Additives for Metal Oxide Based Resists and Precursor Solutions,” incorporated herein by reference. In general, peroxides are prone to radical formation from cleavage of the O—O bond which can be a useful effect for contrast generation within the irradiated areas of the film. However, it can be desirable to offset the formation of such radicals that may occur in non-irradiated regions of the film. From this perspective, in some embodiments, appropriate radical scavenging additives can be combined with the peroxide additives, although these additives should be selected to not directly react with each other under the conditions experienced in the processing. Appropriate amounts of radical scavenging additives are described below.

If peroxides are not added, any peroxides that form would be potentially undesirable with respect to processing, so that additives that react to neutralize the spontaneously formed peroxides may be beneficial. Some of the additives described in the '239 application are reactive with peroxides and are to be avoided in the present context. Other additives in the '239 application are specific for reacting with radicals, which can be desirable in the presently described precursors with added peroxides. Radical scavengers though can neutralize any radicals that do form so that they do not randomly damage the patterning composition and lessen pattern contrast upon irradiation or baking processes such as a PAB or PEB.

Radical scavenger compounds include, for example, H-donor radical scavengers, such as phenolic compounds and hindered amines. The phenolic compounds can be characterized by the presence of a substituted aromatic ring which can improve their ability to form relatively stable radicals after hydrogen atom transfer. In some embodiments, the H-donor radical scavenger is a hindered phenol compound having an aromatic ring substituted with an electron-donating group. In some embodiments, the H-donor radical scavenger is butylated hydroxytoluene (BHT) or butylated hydroxyaniline (BHA), and more general embodiments are described in the '239 application. In some embodiments, the H-donor radical scavenger is an aromatic diol. In some embodiments, the H-donor radical scavenger is an alkoxyphenol, hindered aromatic amine, or derivative thereof.

In some embodiments, the radical scavenging additive is a hindered amine compound. The hindered amine compound can react with oxygen or reactive oxygen species to form a stable and sterically hindered aminoxyl (—NO⁻) radical which can preferentially react with other radical species instead of the non-radical components of the photoresist. In some embodiments, the radical scavenger additive is TEMPO ((2,2,6,6-tetramethylpiperidin-1-yl)oxyl) or TEMPOL ((4-Hydroxy-2,2,6,6-Tetramethylpiperidin-1-yl)oxyl). In some embodiments, the radical scavenger additive is 2-phenyl-4,4,5,5-tetramethylimidazoline-1-oxyl 3-oxide (PTIO).

To enhance the repeatability of patterning with organotin photoresist materials, a desired concentration of peroxide compound can be intentionally introduced to the precursor solution and/or the radiation patternable coating formed therefrom. After this controlled addition, the concentration of peroxide species is more precisely known, and any peroxide species formed through autooxidation can be a mere fraction of the total peroxide concentration. This can mitigate the variable effects of uncontrolled peroxide species formation through autooxidation. Often, the concentration of intentionally introduced peroxide compound should be substantially greater than that of peroxide species formed through autooxidation to realize decreased variation between batches. While not wanting to be limited by theory, it is believed that a chemical equilibrium between peroxide species and alcohols exists such that the intentional addition of a peroxide compound can inhibit further formation of peroxide species through autooxidation. In addition to controlling the peroxide concentration, the addition of a specific peroxide at a selected concentration may provide for the peroxide forming a neutral ligand to the tin ion, which may provide further stabilization of the metal compositions in solution to reduce clustering.

The rupture of the peroxide bonds can also lead to the production of species that can further react with the organotin matrix to promote dealkylation (i.e., rupture of the Sn—C bonds) of organotin species, which can then condense to form Sn—O bonds. While not wanting to be limited by theory, after radiation exposure of the patterning material, the peroxide groups may stabilize radiation cleaved [R] species (which may be R•, R: or a combination thereof), and promote formation of stable compounds from the [R] species that can volatilize for removal from irradiated material. Such effects of the peroxide may reduce the dose for patterning. The formation of condensed Sn—O—Sn bonds drives insolubility of the irradiated material during negative tone imaging. Conversely, the condensation can drive solubility of the irradiated material during positive tone imaging. Exposure of the peroxide-containing material to radiation can drive decomposition of the peroxide O—O bonds and, as the peroxide groups are broken, the corresponding stabilization is lost and the composition can condense to form Sn—O—Sn bonds. Thus, condensation of the tin species can be controlled through radiation exposure and the contrast between non-irradiated and irradiated material can be enhanced by the controlled photosensitive response of the peroxide compounds.

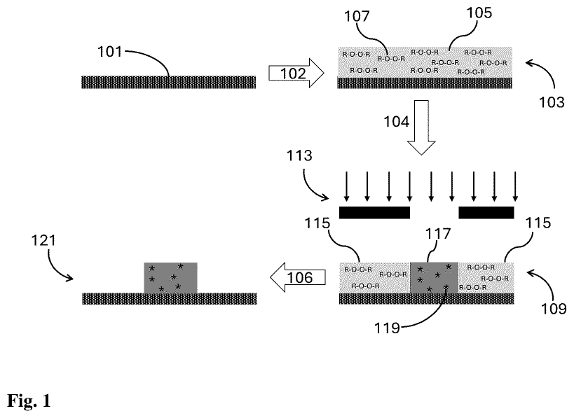

FIG. 1 depicts the formation and patterning of a peroxide-enhanced organotin coating. Peroxide-enhanced organotin coating 105 having peroxide-based composition 107 is formed on substrate 101 via deposition step 102 to form peroxide-enhanced coated substrate 103. Deposition step 102 may use a selected solution coating method to form peroxide-enhanced organotin coating 105. In some embodiments, deposition step 102 may be performed by coating substrate 101 with an organotin precursor solution comprising a mixture of an organotin composition and peroxide-based composition 107. In other embodiments, deposition step 102 may be performed by coating substrate 101 with a precursor solution comprising an organotin composition and a peroxide compound or composition that is a precursor to peroxide-based composition 107. A post-application bake (PAB) may optionally be performed after deposition step 102. Exposure step 104 directs pattern of radiation 113 towards peroxide-enhanced coated substrate 103 to form exposed substrate 109 having irradiated regions 117 and non-irradiated regions 115. Irradiated regions 117 comprise a condensed tin material and peroxide products 119. A post-exposure bake (PEB) may optionally be performed after exposure step 104. As illustrated in FIG. 1, development step 106 is performed to remove non-irradiated regions 117 to form patterned structure 121, which has a negative tone pattern. In other embodiments, development step 106 can remove irradiated regions and form a structure having a positive tone pattern. The inclusion of the peroxide in the patterning material can provide an additional means of generating contrast between the irradiated and non-irradiated regions, which can augment radiation driven dealkylation to achieve the desired contrast and increase the EUV sensitivity of the coating. This can reduce the radiation dose necessary to achieve a desired pattern critical dimension or solubility change, as shown in the examples herein.

Dose reductions can coincide with an increased line width roughness (LWR), as stochastic shot noise effects are exacerbated at lower radiation doses. Peroxide-enhanced organotin coatings can have relatively low increases to LWR accompanying dose reductions. To the extent that radiation dose can be reduced without significantly compromising patterning performance, process times can be reduced since dose effectively correlates with irradiation time, so a reduction in dose increases throughput and increases efficiencies of capital equipment use.

While not wanting to be limited by theory, it is believed that peroxide products formed through the rupture of peroxide bonds can subsequently facilitate condensation in irradiated portions of the peroxide-enhanced organotin coating to increase contrast. Depending on the identity of the peroxide products formed from irradiation, the irradiated coating can have an increased polarity due to the presence of polar oxo-bonds within the peroxide product. Generally, a polarity increase can occur when species formed from the rupture of the peroxide bond enhance further oxidation and/or hydrolysis, thereby constituting a more oxygen-rich material. In some embodiments the peroxide compound contains a peroxydisulfate group, which can generate sulfate moieties that can act as oxygen-rich polar species. The increased polarity of the irradiated coating can reduce the dose necessitated to realize a desired solubility change. Generally, oxygen-rich ligands have a lower affinity for organic developer solutions, such as those used during negative tone development processes, which can improve the quality of negative tone development methods. In the context of positive tone imaging, the incorporation of highly polar ligands can improve wettability and surface interaction of an aqueous and/or basic developer liquid with the photoresist material. The improved wettability allows for better cross-wafer uniformity of the development process. Some peroxide compounds may be more effective to form ligands to the organotin compounds in solution, while other peroxide compounds may more effectively integrate into organotin oxo hydroxo networks in resist coatings to facilitate condensation upon irradiation, and some peroxide compounds may be effective in achieving both of said functionalities. If integrated into the network, the peroxides generally can engage in various hydrogen bonding and other stabilizing interactions and can be described as either compositions or as moieties within the material with an understanding of the overall material complexities. In any case, the peroxides can be proximal to reacting species following irradiation and any subsequent radiation induced thermolysis for potential participation in the reactions. It may be desirable to include blends of peroxide compounds in precursor solutions to achieve particular enhancement of both precursor stabilization and dose reduction for patterning.

### Peroxide Composition

Peroxide functionality can be introduced into the organotin composition through the addition of a peroxide compound or a plurality of peroxide compounds to the organotin precursor solution composition. Depending on the peroxide selected, the peroxide compound can be introduced into the precursor solution as a solution, as a neat liquid, or as a solid. Inorganic peroxide compounds, for example hydrogen peroxide (H₂O₂), and organic peroxide compounds, for example di-tert-butyl peroxide or tert-butyl hydroperoxide, can be used as peroxide additives to organotin photoresist compositions. The peroxide compounds can be added into the organotin photoresist solution through combination of different solutions or through dissolution of solids. In some embodiments, water and a peroxide compound can be mixed to form an aqueous peroxide composition with peroxide compound present at a desired concentration. Commercial aqueous solutions of hydrogen peroxide are available. While commercial hydrogen peroxide solutions can be obtained at very high concentrations, for example 90 wt % special handling may be required due to an explosion risk, so for convenient handling, hydrogen peroxide solutions of roughly 30 wt % are commonly used. Other concentrations are generally commercially available, for example 0.1 wt %, 1 wt %, 2 wt %, 5 wt %, 10 wt %, and 35 wt %, as well as values between these specific values. The concentration of hydrogen peroxide in the aqueous hydrogen peroxide solution can be adjusted via the addition of water to form aqueous hydrogen peroxide solutions from about 0.1 wt % hydrogen peroxide to about 35 wt % hydrogen peroxide in some embodiments, from about 1 wt % to about 30 wt % in other embodiments, and from about 10 wt % to about 25 wt % in further embodiments. The aqueous peroxide composition can be mixed with the organotin photoresist solution to achieve a desired concentration or molar ratio between the peroxide compound and tin (Sn). A person of ordinary skill in the art will recognize that additional ranges of hydrogen peroxide concentrations within these explicit ranges are contemplated and are within the present disclosure.

It can be particularly convenient to incorporate hydrogen peroxide into an organotin precursor solution via the addition of an aqueous peroxide solution because hydrogen peroxide is commercially available in varying concentrations of aqueous solution from chemical suppliers, such as Hawkins, Fisher Scientific, and ULINE. Hydrogen peroxide is also soluble in organic solvents, such as alcohols. Depending on the amount of water to be introduced into the precursor, the available concentrations of hydrogen peroxide or other water-soluble peroxide, it may or may not be desirable to introduce a peroxide into the precursor solution in an aqueous solution.

In some embodiments, the peroxide can be incorporated into the organotin precursor solution via the dissolution of a solid peroxide compound. In some embodiments, the solid peroxide compound is urea hydrogen peroxide. Urea hydrogen peroxide is known to be more stable than an aqueous hydrogen peroxide solution. An amount of urea-hydrogen peroxide complex can be dissolved into the organotin precursor solution to achieve a desired concentration ratio between the peroxide compound and tin (Sn). Upon dissolving, the urea and peroxide are essentially separately dissolved in solution so that hydrogen peroxide can be available as a ligand or for other stabilizing interactions. The dissolution of a solid peroxide compound can provide an additional advantage of not impacting water concentration as an aqueous peroxide composition can. The addition of a solid peroxide composition can produce a peroxide-stabilized precursor solution without substantially impacting the water concentration of the precursor solution. Urea can decompose into volatile species with heating above roughly 160° C.

In the broadest sense, a suitable peroxide compound is generally characterized as having at least one peroxide O—O bond or a peroxide functional group. The terms peroxide bond, O—O, peroxo bond, and peroxide group synonymously refer to a chemical linkage involving an oxygen-oxygen single bond and can be used interchangeably. The functionality of the additive is primarily derived from the peroxide bond, although the identity of substituents can provide further advantages. In some embodiments, the peroxide compound can be represented by the structure:

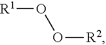

wherein R¹ and R² are independently H, a linear, cyclic, or branched alkyl or aryl group having from about 1 to about 15 carbon atoms. In some embodiments wherein both R¹ and R² are H, the peroxide compound can be hydrogen peroxide. In some embodiments wherein the peroxide compound is a hydroperoxide, R¹ is H and R² can be a linear, cyclic, or branched alkyl or aryl group having from about 1 to about 15 carbon atoms, for example tert-butyl hydroperoxide. In some embodiments wherein R¹ and R² are both a linear, cyclic, or branched alkyl or aryl group having from about 1 to about 15 carbon atoms, the peroxide compound is an organic peroxide, for example dimethyl peroxide or dicumyl peroxide (C₆H₅C(CH₃)₂—O—O—C(CH₃)₂C₆H₅). R¹ and R² can also comprise heteroatoms, such as oxygen, and a representative compound di-benzoyl peroxide (C₆H₅CO—O—O—COC₆H₅). Organic peroxides can be liquids or solids. Generally, an organic peroxide should be selected for appropriate solubility in the precursor solution solvent. Bulky organic groups can be advantageous with respect to improving contrast upon irradiation since rupture of the peroxide bond can free organic species to leave the material and increase condensation of the irradiated material.

In some embodiments, the peroxide compound contains a peroxydisulfate group, for example a bis-organo peroxydisulfate or other derivative of persulfate represented by the structure:

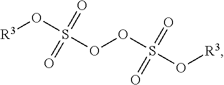

wherein R³ is H or an organo group, such as a linear, cyclic, or branched alkyl or aryl group having from about 1 to about 15 carbon atoms. In some embodiments R³ is H and the peroxide compound is peroxydisulfuric acid. The conjugate base of peroxydisulfuric acid is peroxydisulfate, which is available as salts, such as ammonium peroxydisulfate. In other embodiments R³ is an organic group. Bulky organic groups can be desirable, such as aromatic groups or t-butyl groups. An exemplified aromatic group for these peroxides, see below, is ethylbenzene, and the peroxide compound is O,O-bis-ethylphenyl peroxydisulfate. While the organo peroxydisulfate compounds are strong oxidizing agents, they are generally relatively stable. Illustrative non-limiting embodiments of useful organic peroxydisulfate derivatives are represented by the structures:

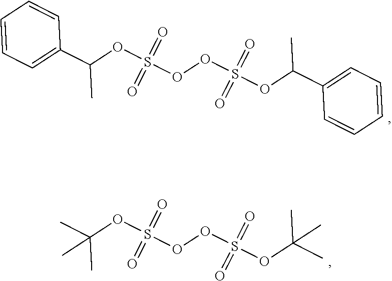 [SMILES: CC(OS(=O)(=O)OOS(=O)(=O)OC(C)c1ccccc1)c1ccccc1 ; CC(C)(C)OS(=O)(=O)OOS(=O)(=O)OC(C)(C)C]

While peroxydisulfuric acid and salts involving peroxydisulfate anions are known, the formation of the organic derivatives does not seem to have been reported. A synthesis pathway to effectively form the organic sulfate groups without disrupting the peroxide bonds are described herein. Bis-organo peroxydisulfate compounds can generally be formed through the following double displacement reaction between a halocarbon and peroxydisulfate salt:

2 R′X+M₂S₂O₈→R′₂S₂O₈+2 MX

wherein R′ is a linear, cyclic, or branched alkyl or aryl group having from about 1 to about 11 carbon atoms, M is an alkali metal such as Li, Na, K, Rb, or Cs, and X is a halogen such as F, Cl, Br, or I. In some embodiments, M can be ammonium (NH₄⁺). Peroxydisulfate salts such as sodium peroxydisulfate, potassium peroxydisulfate, and ammonium peroxydisulfate are readily available from chemical suppliers such as Merck, Thermo Fisher Scientific, and Sigma Aldrich, as are halocarbons. The identity of the hydrocarbyl substituents, R′, can generally be controlled through the selection of an appropriate halocarbon reactant comprising a hydrocarbyl substituent substituted with a halogen at a specific position. In some embodiments, R′X can be a haloalkene while in other embodiments R′X can be a haloarene. The hydrocarbyl substituents generally bond to oxygen atoms of the peroxydisulfate group at the halogen-substituted position of the halocarbon reactant.

Generally, the synthesis of bis-organobis-organo peroxydisulfate compounds can be accomplished by combining the peroxydisulfate salt and the halocarbon in a suitable vessel, for example a flask, beaker, tube, or cylinder to form a reaction mixture. If the halocarbon is a suitable liquid, then the two reactants can be combined without the use of a separate solvent. However, in some embodiments a solvent can optionally be used to improve the reaction rate although peroxydisulfate-based salts are generally known to have low solubility in many common organic solvents. In some embodiments, the use of water as a solvent, while providing solubility for the peroxydisulfate salt, can contribute to the undesirable decomposition of the final product. The peroxydisulfate-based salts also generally have low solubility in halocarbon reactants, but the reaction gradually results in further dissolving of the salt as it is consumed in the liquid so that the reaction can proceed sufficiently to completion. The use of an organic solvent can be particularly desirable if the halocarbon reactant is not a liquid. In general, the by-product halide salts precipitate and can be removed by filtration. A stoichiometric ratio of both halocarbon and peroxydisulfate salt can be effective for the synthesis, although in theory other ratios of reactants can be used to fine tune the kinetics of the reaction to achieve desirable reaction rates and conversions. In some embodiments, the ratio of halocarbon to peroxydisulfate salt is from about 0.25:1 to about 4:1, while in other embodiments the ratio is from about 0.5:1 to about 2.2:1, and about a 2:1 stoichiometric ratio in further embodiments. The reaction mixture can then be allowed to react under controlled conditions to form a bis-organo peroxydisulfate compound. In some embodiments, the reaction can be allowed to react from about 0.1 minutes to about 1 day, from about 30 minutes to about 12 hours in some embodiments, and from about 1 hour to about 4 hours in further embodiments. In some embodiments, the reaction can be stirred while it is allowed to react which can increase the consistency and/or rate of the reaction. The reaction mixture can be allowed to react in a controlled environment at a selected temperature or range of temperatures, including room temperature (generally about 20° C. to about 24° C.). The selected temperature may be influenced by the solvent selection. In some embodiments, the reaction mixture is allowed to react at a controlled temperature from about −30° C. to about 65° C. A person or ordinary skill in the art will recognize that additional ranges of reactant ratio, reaction durations, and temperatures within the explicit ranges above are contemplated and are within the present disclosure.

Following completion of the reaction, the reacted mixture can then be purified to produce a high purity bis-organo peroxydisulfate compound. In some embodiments wherein the bis-organo peroxydisulfate compound is a liquid, the reacted mixture can be filtered to remove solid alkali metal halides or ammonium halides, MX, and form a filtered reacted product. Filtering may also remove any unreacted, undissolved peroxydisulfate salt. The filtered compound can be further purified through a vacuum drying process to form a dried reacted product. The drying can remove any unreacted halocarbon. Some mild heating may be suitable, but the temperature should be controlled to avoid decomposing the peroxide. The dried reacted product is generally a high purity bis-organo peroxydisulfate, which can be characterized by ¹H or ¹³C NMR spectra of the dried product displaying prominent shifts associated with the compound and a low number of shifts associated with impurities that can be present. In an exemplified embodiment, the yield of di-hydrocarbyl peroxydisulfate was around 70%, although variations in reaction species, controlled environment conditions, and reaction durations can impact the yield. In any case, the reaction can be performed with a relatively high yield. The synthesis of the bis-organo peroxydisulfate compound O,O-bis ethylphenyl peroxydisulfate is detailed in the examples herein.

### Precursor Solution

The various components of the peroxide-stabilized organotin photoresist precursor solutions can generally be combined in any order to achieve the desired ratios and concentrations of the individual components. For example, the organotin precursor composition(s) can be first combined with the solvent followed by addition of the peroxide composition. Alternatively, the peroxide composition can be first combined with the solvent followed by addition of the organotin precursor composition(s). In some embodiments, the organotin precursor composition(s) are first combined and mixed with the solvent prior to addition of the peroxide composition. Generally, the peroxide-stabilized precursor can be prepared in an inert environment to reduce environmental contaminants and undesirable reactions. The inert environment can comprise nitrogen, a noble gas such as argon, or a combination thereof. Following preparation, the peroxide-stabilized precursor can be transferred to a container and subsequently sealed to further reduce environmental contaminants during storage and form a sealed peroxide-stabilized precursor solution. Suitable containers can be relatively inert with respect to the precursor solution, for example plastic bottles made of high-density polyethylene (HDPE), polytetrafluoroethylene (PTFE), or polypropylene (PP) or CLEANBARRIER™ bottles manufactured by Aicello.

The organotin compositions can generally comprise one or more distinct compounds each represented by the formula RₙSnL₄₋ₙ, where n=1, 2, or 3 and where R forms a carbon-tin bond that can optionally comprise heteroatoms, which are not carbon or hydrogen. In the cases where multiple tin species are present in the organotin composition as a blend, the overall formula of the blend can generally be represented by the averaged formula RₙSnL₄₋ₙ, where 0.5<n<2. As noted above, for convenience as well as consistency in the art, R can be interchangeably referred to as an alkyl ligand, organo ligand or hydrocarbyl ligand. The hydrolysable ligand, L, generally includes ligands that can be hydrolyzed with water, such as alkoxides (hydrocarbyl oxide, OR′), acetylides (C≡CR′), carboxylates (O₂CR′), or amides (NR′₂). In some embodiments, R′ is a linear, branched, cyclic, or aromatic hydrocarbyl group having from 1 to 10 carbon atoms. In some embodiments, R′ can include methyl, ethyl, propyl, propyl, butyl, pentyl, silyl, any of their respective isomers, and combinations thereof. In some embodiments, branched alkyl ligands can be desirable for some patterning compositions where the compound can be represented generally as R¹R²R³CSn O_{(2-(z/2-(x/2))}(OH)ₓ, where R¹, R² and R³ are independently hydrogen or an alkyl group with 1-10 carbon atoms. Similarly, this representation of alkyl ligand R is similarly applicable to the other embodiments generally with R¹R²R³CSn(L)₃, with L corresponding to hydrolysable ligands, such as alkoxide (hydrocarbyl oxide), acetylide, carboxylate, or amide moieties. In some embodiments, R¹ and R² can form a cyclic alkyl moiety, and R³ may also join the other groups in a cyclic moiety. Suitable branched alkyl ligands can be, for example, isopropyl (R¹ and R² are methyl and R³ is hydrogen), tert-butyl (R¹, R² and R³ are methyl), tert-amyl (R¹ and R² are methyl and R³ is —CH₂CH₃), sec-butyl (R¹ is methyl, R² is —CH₂CH₃, and R³ is hydrogen), neopentyl (R¹ and R² are hydrogen, and R³ is —C(CH₃)₃), cyclohexyl, cyclopentyl, cyclobutyl, and cyclopropyl. Examples of suitable cyclic groups include, for example, 1-adamantyl (—C(CH₂)₃(CH)₃(CH₂)₃ or tricyclo(3.3.1.13,7) decane bonded to the metal at a tertiary carbon) and 2-adamantyl (—CH(CH)₂(CH₂)₄(CH)₂(CH₂) or tricyclo(3.3.1.13,7) decane bonded to the metal at a secondary carbon). In other embodiments, hydrocarbyl groups may include aryl or alkenyl groups, for example, benzyl or allyl, or alkynyl groups. In other embodiments, the hydrocarbyl ligand R may include any group consisting solely of C and H and containing 1-31 carbon atoms. In summary, some examples of suitable alkyl groups bonded to tin include, for example, linear or branched alkyl (i-Pr ((CH₃)₂CH—), t-Bu ((CH₃)₃C—), Me (CH₃—), n-Bu (CH₃CH₂CH₂CH₂—)), cyclo-alkyl (cyclo-propyl, cyclo-butyl, cyclo-pentyl), olefinic (alkenyl, aryl, allylic), or alkynyl groups, or combinations thereof. In further embodiments, suitable R groups may include hydrocarbyl groups substituted with hetero-atom functional groups including cyano, thio, silyl (and germanium analogs), ether, keto, ester, or halogenated groups or combinations thereof, such as one or more fluorine atoms and/or on or more iodine atoms. As is conventional in this art, the hydrocarbyl group can be referred to as an alkyl group even though the group can have unsaturated bonds, aryl groups, heteroatoms, and so forth.

Recent synthesis efforts have resulted in commercially practical approaches to form compositions with a greater range of R ligands, as described in published U.S. patent application 2024/0199658 to Jilek et al., entitled “Direct Synthesis of Organotin Alkoxides,” U.S. Pat. No. 10,787,466 to Edson et al., entitled “Monoalkyltin compositions with low polyalkyl tin contamination, their compositions and methods”, and published U.S. patent application 2022/0064192 to Edson et al., entitled “Methods to produce organotin compositions with convenient ligand providing reactants”, all of which are incorporated herein by reference. In particular, Applicant has developed effective synthesis processes to effectively incorporate various heteroatoms into R groups. As described in the aforementioned references, various heteroatoms can be introduced into the ligands, including F, I, N and O atoms. Various organotin compositions with heteroatoms in the R group can be desirable for blending to introduce certain characteristics to the resist.

In some embodiments, the organotin composition comprises a mixture of organotin compounds having different hydrocarbyl R groups with the same and/or different L groups bound accordingly. In some embodiments, the organotin photoresist composition has R ligands comprising a blend of a linear alkyl ligand and a non-linear alkyl ligand. In some embodiments, a blend of a linear alkyl ligand and a non-linear alkyl ligand comprises a branched alkyl group, a cyclo-alkyl group, or an aryl group. In some embodiments, the organotin composition is a mixture of distinct organotin compounds having methyl ligands and tert-butyl ligands, respectively. In some embodiments, the precursor compositions comprise a blend of organotin compounds having the same and/or different L groups. In some embodiments, the organotin composition comprises distinct organotin compounds with L ligands comprising a dialkylamide, an alkylsilylamide, an alkyloxide, an alkylacetylide, or a combination thereof. In other embodiments, the organotin composition comprises distinct organotin compounds with L ligands comprising methoxide, ethoxide, propoxide, iso-propoxide, butoxide, iso-butoxide, tert-butoxide, tert-amyloxide, pentoxide, iso-pentoxide, dimethyl amide, diethyl amide, diiso-propyl amide, trimethylsilyl amide, other isomers thereof, or combinations thereof. In embodiments wherein a blend of different organotin compounds are used, any one of the distinct organotin compounds can comprise from about 1 mol. % to about 99 mol. % of the total organotin moles in some embodiments, from about 5 mol. % to about 95 mol. % of the total organotin moles in other embodiments, from about 10 mol. % to about 90 mol. % of the total organotin moles in other embodiments, and from about 15 mol. % to about 85 mol. % of the total organotin moles in further embodiments. A minority organotin component thus can comprise generally at least about 1 mol %, in further embodiments at least about 2.5 mol % and in other embodiments at least about 5 mol %. Blends can comprise two, three, four or more distinct organotin components. In the Examples below, organotin precursor solutions comprising a mixture of two distinct alkyltin tri-tert-amyl alkoxide compounds are demonstrated. As is conventional in this art, the hydrocarbyl group can be referred to as an alkyl group even though the group can have unsaturated bonds, aryl groups, heteroatoms, and so forth. A person of ordinary skill in the art will recognize that additional ranges of organotin precursor contributions in an organotin precursor solution within the explicit ranges above are contemplated and are within the present disclosure.

The peroxide-stabilized organotin photoresist precursor solutions generally comprise one or more organotin precursor compositions, a peroxide compound, and an organic solvent. In some embodiments, a plurality of peroxide compounds can be included. The resist precursor composition can be conveniently specified based on tin ion molar concentration. In general, the resist precursor solution generally comprises from about 0.0025 M to about 1 M tin cation, in some embodiments from about 0.004 M to about 0.9 M, in further embodiments from about 0.005 M to about 0.75 M, in some embodiments from about 0.01 M to about 1 M, and in additional embodiments from about 0.01 M to about 0.5 M tin cation. The precursor composition further comprises a peroxide composition and may comprise a plurality to provide improved precursor stability as well as lower doses for effective patterning. For example, in some embodiments, the peroxide compound comprises hydrogen peroxide. Hydrogen peroxide can comprise an aqueous solution that can be added and mixed into the organotin photoresist solution, though other sources of hydrogen peroxide may be used. If aqueous hydrogen peroxide solution or other aqueous peroxide composition solution is added, the water added with the peroxide can be accounted for in the adjustment of the total water content. The peroxide compound(s) can generally be added to the organotin photoresist composition to achieve a desired molar ratio between the peroxide compound(s) and tin compounds. The peroxide compound(s) need not be present at a high concentration to provide functionality. In some embodiments, the peroxide-stabilized organotin composition can have a peroxide to Sn molar ratio in various embodiments: from about 0.00005 to about 2.5, from about 0.0005 to about 2.25, from about 0.005 to about 2.0, from about 0.025 to 1.5, from about 0.1 to about 0.5, from about 0.15 to about 0.75 in other embodiments, and from about 0.2 to about 1.25 in further embodiments. Similarly, a precursor solution can comprise a peroxide compound at a molar concentration from about 0.000003M to about 2.5M in some embodiments, from about 0.0003 M to about 1.0 M in other embodiments, from about 0.001M to about 0.5M, and from about 0.005 M to about 0.25 M in further embodiments. As noted above, in some embodiments, the precursor compositions can further comprise a radical scavenger, appropriately selected as described above. In some embodiments, the radical scavenging additive can be present in the organotin photoresist composition in a molar ratio of radical scavenging additive to Sn in a range from a lower limit of about 0.00002, in other embodiments about 0.00005, in further embodiment about 0.000075, in additional embodiments about 0.00001 to an upper limit independently of any one of about 0.5, in some embodiments of about 0.6, in further embodiments of about 0.75 in some embodiments, and in additional embodiments of about 0.8. Similarly, a precursor solution can comprise radical scavenging additive at a concentration from about 0.000001M to about 0.4M in further embodiments form about 0.000002M to about 0.3M, in additional embodiments from about 0.0000035M to about 0.25M, in some embodiments from about 0.000004M to about 0.2M, and in further embodiments from about 0.000005M to about 0.15M, or any range with any one of these lower molarity limits with any one of the explicit upper molarity limits. Other ranges for molar ratios of peroxide compounds to Sn, radical scavenger compounds to Sn. and concentrations thereof not directly disclosed but within the above ranges are contemplated and are within the scope of the present disclosure.

It can be desirable to control the amount of water in the peroxide-stabilized organotin photoresist composition to a specific level. As described herein, water can react with the organotin species to form hydrolysis/condensation products. Organotin photoresist solutions comprising different amounts of water can result in different degrees of hydrolysis/condensation occurring and thus different distributions of hydrolysis/condensation products within the different solutions which may impact resist performance. Therefore, to improve batch to batch reproducibility of organotin photoresist solutions it is desirable to controllably target specific concentrations of water formulated into the photoresist solutions. Water can be added as a component of the peroxide composition, for example as part of the aqueous solution of the peroxide compound added to form the peroxide-stabilized organotin photoresist solution, and/or it can be added separately to achieve a desired final concentration of water in the peroxide-stabilized organotin photoresist solution. Desirable amounts of water can generally be expressed as either absolute concentrations, such as parts-per-million by weight (ppm) or molarity, or the desirable amounts of water can be expressed as molar ratios with respect to the Sn concentration. In some embodiments, the peroxide-stabilized organotin photoresist solutions can comprise a selected concentration of water from about 200 ppm to about 10,000 ppm water, from about 250 ppm to about 8,000 ppm, from about 275 ppm to about 3,000 ppm in further embodiments, and from about 300 ppm to about 1,500 ppm in other embodiments. In some embodiments, the peroxide-stabilized organotin photoresist solutions can comprise a selected molar ratio of water to Sn from about 0.1 to about 20, from about 0.2 to about 15 in some embodiments, and from about 0.3 to about 10. A person of ordinary skill in the art will understand that additional ranges of water concentrations within the explicit ranges above are contemplated and are within the present disclosure.

The peroxide-stabilized organotin solution can generally comprise any useful solvent compatible with semiconductor manufacturing and with the organotin photoresist composition. Suitable solvents can include alcohols, alkanes, aromatic hydrocarbons, ethers, esters, ketones, and combinations and mixtures thereof. Suitable organic solvents include, for example, alcohols or blends thereof. Generally, the solvents are at least 50 weight percent alcohols with any remaining organic solvent liquids being soluble in the alcohol, such as an alkane (such as pentane or hexane), an aromatic hydrocarbon (such as toluene), ether (such as diethyl ether, C₂H₅OC₂H₅), or mixtures thereof. In some embodiments, the solvent is at least 90 weight percent alcohol, and the solvent can be effectively alcohol with just trace impurities of other compounds. Suitable alcohols are generally alcohols with a melting point of no more than about 10° C., such as methanol, ethanol, propanol, butanol, pentanol, hexanol, heptanol, octanol, nonanol, decanol, branched versions thereof, and mixtures thereof.

### Coating and Patterning Material

The peroxide-stabilized organotin photoresist precursor solutions can be used to form radiation-patternable peroxide-enhanced organotin oxide hydroxide coatings, and such coatings can be formed using any suitable method known in the art. The coating process along with the pre-irradiation process, described further below, generally results in removal of solvent and hydrolysis of hydrolysable ligands. As a result, an organotin oxo-hydroxo network is formed. The peroxide composition integrates into the organotin oxo hydroxo network as a ligand to tin and/or as a moiety within the network. Generally, the mole ratios of tin and peroxide from the precursor solution are carried over into the resulting coating and dried film as a layer on the substrate. Thus, the mole ratios of peroxide composition or functional groups to tin can be from about 0.00005 to about 2.5, from about 0.0005 to about 2.25, from about 0.005 to about 2.0, from about 0.025 to 1.5, from about 0.1 to about 0.5, from about 0.15 to about 0.75 in other embodiments, and from about 0.2 to about 1.25 in further embodiments. In some embodiments and owing to relatively low boiling points in comparison to other peroxide compounds, hydroperoxides can volatize to an extent during coating and be present at a lower concentration in the dried film than the precursor solution. The concentration of hydroperoxide or any other more volatile peroxide in the precursor solution can be precisely selected to realize a desired concentration of hydroperoxide in the film after coating and drying. A person of ordinary skill in the art will understand that additional ranges of peroxide to tin ratios within the explicit ranges above are contemplated and are within the present disclosure.

Spin coating can be particularly desirable for forming coatings using the peroxide-stabilized organotin photoresist compositions. In a typical spin coating process, a volume of a photoresist precursor solution is introduced onto the surface of a substrate, and the substrate is rotated at high speeds to drive rapid evaporation and hydrolysis processes to enable the formation of a radiation patternable coating. In some embodiments, the substrate can be spun at rates (i.e., spin speeds) from about 500 rpm to about 10,000 rpm, in further embodiments from about 1000 rpm to about 7500 rpm, and in additional embodiments from about 2000 rpm to about 6000 rpm. The spin speed can be adjusted to obtain a desired coating thickness. The spin coating can be performed from about 5 seconds to about 5 minutes and in further embodiments from about 15 seconds to about 2 minutes. An initial low speed spin, e.g., at 50 rpm to 250 rpm, can be used to perform an initial bulk spreading of the composition across the substrate. A back side rinse, edge bead removal step, or the like can be performed with water or other suitable solvent to remove any edge bead. A person or ordinary skill in the art will recognize that additional ranges of spin coating parameters within the explicit ranges above are contemplated and are within the present disclosure.

A substrate generally presents a surface onto which the coating material can be deposited, and the substrate may comprise a plurality of layers in which the surface relates to an upper most layer. The substrate surface can be treated to prepare the surface for adhesion of the coating material. Prior to preparation of the surface, the surface can be cleaned and/or smoothed as appropriate. Suitable substrate surfaces can comprise any reasonable material. For semiconductor applications, a suitable substrate generally comprises a semiconductor wafer. Some substrates of interest include, for example, silicon wafers, silica substrates, other inorganic materials, polymer substrates, such as organic polymers, composites thereof and combinations thereof and/or in layers of the substrate. In some embodiments, the substrate can comprise a patterned structure such as described by Stowers et al. in U.S. Pat. No. 10,649,328, entitled “Pre-Patterned Lithography Templates, Process Based on Radiation Patterning Using The Templates And Processes To Form The Templates”, incorporated herein by reference.

The thickness of the coating generally can be a function of the precursor solution concentration, volume delivered, viscosity, and the spin speed for spin coating. For other coating processes, the thickness can generally also be adjusted through the selection of the coating parameters. In some embodiments, it can be desirable to use a thin coating to facilitate formation of small and highly resolved features in the subsequent patterning process. For example, the coating materials after drying can have an average thickness of no more than about 250 nanometers (nm), in additional embodiments from about 1 nm to about 50 nm, in other embodiments from about 2 nm to about 40 nm and in further embodiments from about 3 nm to about 25 nm. A person of ordinary skill in the art will recognize that additional ranges of thicknesses within the explicit ranges above are contemplated and are within the present disclosure. The thickness can be evaluated using non-contact methods, such as x-ray reflectivity and/or ellipsometry, based on the optical properties of the film. In general, the coatings are relatively uniform to facilitate processing. In some embodiments, such as high uniformity coatings on reasonably sized substrates, the evaluation of coating uniformity or flatness may be evaluated with, for example, a 1-centimeter edge exclusion, i.e., the coating uniformity is not evaluated for portions of the coating within 1 centimeter of the edge, although other suitable edge exclusions can be selected.

While heating may not be needed for successful application of the deposition process, it can be desirable to heat the coated substrate in a post-application baking step (PAB) to densify the coating material, to speed the processing, to increase the reproducibility of the process, and/or to facilitate vaporization of solvent and the hydrolysis by-products, such as alcohols and/or amines. In embodiments in which heating of the coated substrate is performed prior to irradiation, the coated substrate can be heated to temperatures from about 45° C. to about 250° C., and in further embodiments from about 55° C. to about 225° C. The peroxides can influence selection of bake temperature if decomposition of the peroxides is to be avoided. The PAB can be performed at a selected pressure, such as ambient pressure or reduced pressure, under an atmosphere of air or inert gas. The heating can generally be performed for at least about 0.1 minute, in further embodiments for about 0.5 minutes to about 30 minutes, and in additional embodiments from about 0.75 minutes to about 10 minutes. A person of ordinary skill in the art will recognize that additional ranges of PAB temperatures and times within the explicit ranges above are contemplated and are within the present disclosure. A rest step can be included between coating and irradiation, which can be performed under a selected atmosphere and pressure.

Generally, photoresist coatings can be patterned using radiation. Suitable radiation sources include extreme ultraviolet (EUV), ultraviolet (UV), or electron beam (EB) radiation. For fabrication of semiconductor devices, EUV radiation can be desirable due to its higher resolution compared to UV radiation, and its higher throughput compared to electron beam (EB)-based processing. Radiation can generally be directed to the substrate material through a mask or a radiation beam can be controllably scanned across the substrate to form a latent image within the resist coating. For EUV “masking”, the patterns are formed using mirrors to reflect and direct light from a plasma source.

The amount of electromagnetic radiation can be characterized by a fluence or dose which is obtained by the integrated radiative flux over the exposure time. For embodiments in which EUV radiation is used, suitable radiation doses can be from about 1 mJ/cm² to about 150 mJ/cm², in further embodiments from about 2 mJ/cm² to about 100 mJ/cm² and in further embodiments from about 3 mJ/cm² to about 50 mJ/cm². A person of ordinary skill in the art will recognize that additional ranges of radiation doses within the explicit ranges above are contemplated and are within the present disclosure.

Following exposure to radiation and the formation of a latent image, a subsequent post-exposure bake (PEB) is typically performed. In some embodiments, the PEB can be performed at temperatures from about 45° C. to about 250° C., in additional embodiments from about 50° C. to about 190° C. and in further embodiments from about 90° C. to about 185° C. Again, the selection of a temperature for the PEB may be influenced by the thermal stability of the peroxide compound. A PEB can be performed at a selected pressure, such as ambient pressure or reduced pressure, under air, a reactive gas, such as enhanced amounts of carbon dioxide, or under an inert atmosphere, such as nitrogen or noble gas. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of PEB temperatures and times within the explicit ranges above are contemplated and are within the present disclosure. A PEB process can be divided into steps that may be performed under different atmospheres and/or at different temperatures, and rest steps can also divide the PEB processing including the time between irradiation and development, between heating steps and/or before or after heating is performed, in which each different process step can be for a selected period of time. Rest steps can be performed for longer periods of time relative to heating steps, such as for more than 30 minutes.

Following performing a PEB, development of the image involves the contact of the patterned coating material including the latent image to a developer composition to remove either the un-irradiated coating material to form the negative image or the irradiated coating to form the positive image. Irradiated regions of organotin oxide hydroxide coatings are generally hydrophilic and are thus soluble in aqueous bases and insoluble in organic solvents; conversely, non-irradiated regions are generally hydrophobic and are thus soluble in organic solvents and insoluble in aqueous bases. For negative tone imaging, the developer can be an organic solvent, such as the solvents used to form the precursor solutions.

For positive tone imaging, suitable developers can generally be aqueous bases. To reduce contamination from the developer, it can be desirable to use a developer that does not have metal atoms. Thus, quaternary ammonium hydroxide compositions, such as tetraethylammonium hydroxide, tetrapropylammonium hydroxide, tetrabutylammonium hydroxide or combinations thereof, are desirable positive tone developers. In general, the quaternary ammonium hydroxides of particular interest can be represented with the formula R₄NOH, where R=a methyl group, an ethyl group, a propyl group, a butyl group, or combinations thereof. The coating materials described herein generally can be developed with the same developer commonly used presently for polymer resists, specifically tetramethyl ammonium hydroxide (TMAH). Commercial TMAH is available at 2.38 weight percent. Furthermore, mixed quaternary tetraalkyl ammonium hydroxides can be used. In some embodiments, the developer can comprise from about 0.5 to about 30 weight percent tetraalkyl ammonium hydroxides, in further embodiments from about 1 to about 25 weight percent tetraalkyl ammonium hydroxides and in other embodiments from about 1.25 to about 20 weight percent tetraalkylammonium hydroxides. A person of ordinary skill in the art will recognize that additional ranges of developer concentrations within the explicit ranges above are contemplated and are within the present disclosure.

For the negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity, and potential chemical interactions with other process material. In particular, suitable developers include, for example, aromatic compounds (e.g., benzene, xylenes, toluene), esters (e.g., propylene glycol monomethyl ester acetate (PGMEA), ethyl acetate, ethyl lactate, n-butyl acetate, butyrolactone), alcohols (e.g., 4-methyl-2-pentanol, 1-butanol, isopropanol, 1-propanol, methanol), ketones (e.g., methyl ethyl ketone, acetone, cyclohexanone, 2-heptanone, 2-octanone), ethers (e.g., tetrahydrofuran, dioxane, anisole) and the like. Improved developer compositions have been described in published U.S. Patent Application No.: 2020/0326627 to Jiang et al. (hereinafter the '627 application), entitled “Organometallic Photoresist Developer Compositions and Processing Methods,” incorporated herein by reference. Improved developer solutions generally comprise a reference organic solvent composition and an additive composition having a higher polarity and/or hydrogen-bonding character than the reference solvent composition. In one example, an improved developer composition can comprise PGMEA and acetic acid. The development can be performed for about 5 seconds to about 30 minutes, in further embodiments from about 8 seconds to about 15 minutes and in addition embodiments from about 10 seconds to about 10 minutes. A person of ordinary skill in the art will recognize that additional ranges within the explicit ranges above are contemplated and are within the present disclosure.

For negative tone development, developer selection can be effectively influenced by solubility parameters with respect to the coating material, both irradiated and non-irradiated, as well as developer volatility, flammability, toxicity, viscosity and potential chemical interactions with other process material. See the developers in the '627 application cited above. In particular, developers can have differing amounts of more polar or less polar components, which can be specified more specifically with solubility parameters. In some embodiments, the solvent blend can comprise at least two solvents with at least 55 volume % of one or more solvents each independently having a sum of Hansen solubility parameter δH+δP of no more than about 16 (J/cm³)^{1/2}, and with from about 0.25 volume % to about 45 volume % of one or more solvents each independently having a sum of Hansen solubility parameter δH+δP of at least about 16 (J/cm³)^{1/2} As noted below, for double bake-double develop processing, the second development can involve a developed for a negative tone pattern can comprise all or a larger percentage of a solvent having a sum of Hansen solubility parameter δH+δP of at least about 16 (J/cm³)^{1/2}, or a positive tone developer can be used in the second step of a negative tone patterning process.

Alternatively, or additionally, solventless development, also referred to as dry development, can be employed with the organotin materials described herein. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Patent Application No. 2023/0100995 to Cardineau et al., entitled “High Resolution Latent Image Processing and Thermal Development”, both of which are incorporated herein by reference. In such dry development processes, development can be achieved by exposing the irradiated substrate to a plasma or a thermal process while flowing a gas comprising a small molecule reactant that facilitates removal of irradiated or non-irradiated regions. Following development, a rinse step can be conducted to further improve pattern fidelity, and such methods have been described, for example, in published U.S. Patent Application No. 2020/0124970 to Kocsis et al., entitled “Patterned Organometallic Photoresists and Methods of Patterning,” incorporated herein by reference. Effective etching methods for developing these organotin resists have been developed, see U.S. Pat. No. 11,079,682 to Han et al., entitled “Method for Extreme Ultraviolet (EUV) Resist Patterning Development,” incorporated herein by reference.

After completion of the development step and any optional rinses, the patterned wafers can be treated to further condense the patterned material and to further dehydrate, densify, or remove residual developer from the material. The treatment can involve heat, exposure to a suitable plasma, and/or exposure to radiation. A heat treatment can be particularly desirable for embodiments in which the oxide coating material is incorporated into the ultimate device, although it may be desirable to perform the heat treatment for some embodiments in which the coating material is used as a resist for pattern transfer and ultimately removed if the stabilization of the coating material is desirable to facilitate further patterning. In particular, the bake of the patterned coating material can be performed under conditions in which the patterned coating material exhibits desired levels of etch selectivity. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiment for about 2 minutes to about 1 hour, in further embodiments from about 2.5 minutes to about 25 minutes. The heating may be performed in air, vacuum, or an inert gas ambient, such as Ar or N₂. A person of ordinary skill in the art will recognize that additional ranges of temperatures and time for the heat treatment within the explicit ranges above are contemplated and are within the present disclosure. Likewise, nonthermal treatments, including blanket UV exposure, or exposure to an oxidizing plasma such as O₂ may also be employed for similar purposes. Following development, the physically patterned structure can be further processed for device formation using, for example, conventional processing.

### EXAMPLES

### Example 1: Hydrolytic Stability Improvement of Peroxide-Stabilized Organotin Photoresist Precursor Solutions

This example demonstrates improvements in stability of organotin photoresist precursor solutions with respect to precipitation via the use of aqueous peroxide as an additive.

A first stock solution of an organotin photoresist precursor (Precursor Solution A) was prepared by dissolving an appropriate mass of tert-butyl tin tris(tert-amyloxide) (tBuSn(OtAmyl)₃) into 4-methyl-2-pentanol to form an organotin precursor solution having a tin concentration of 0.044 M [Sn]. A second stock solution of an organotin photoresist precursor solution having a blend of organotin precursors (Precursor Solution B) was prepared by dissolving appropriate masses of tBuSn(OtAmyl)₃ and MeSn(OtAmyl)₃ in a 4:1 ratio in 4-methyl-2-pentanol to form an organotin precursor solution with a total tin concentration of 0.05 M. The solvent for both solutions was adjusted to 300 ppm water. A series of precursor solution samples A1-A6 were then prepared by transferring, in an Ar-filled glovebox, 10 mL of Precursor Solution A into separate vials, followed by the addition of 10 μL, 60 μL, or 100 μL aliquots of water (Samples A1-A3, respectively) or 10 μL, 60 μL, or 100 μL aliquots of 30 wt. % H₂O₂(aq) (Samples A4-A6, respectively). A series of precursor solution samples B1-B6 were prepared by transferring, in an Ar-filled glovebox, 10 mL of Precursor Solution B into separate vials, followed by the addition of 10 μL, 60 μL, or 100 μL aliquots of water (Samples B1-B3, respectively) or 10 μL, 60 μL, or 100 μL aliquots of 30 wt. % H₂O₂(aq) (Samples B4-B6, respectively). Each sample was then mixed to prepare a series of organotin precursor solutions having either a first organotin precursor or a blend of a first organotin precursor and a second organotin precursor and specific concentration ratios of H₂O:Sn and H₂O₂:Sn, as shown in Table 1. Each sample was observed and visually inspected for precipitation (indicated by Ppt. observed) after 30 days, and the results are shown in Table 1. “Y” indicates that precipitation was observed after 30 days, “N” indicates that no precipitation was observed after 30 days, and “sl.” indicates that slight precipitation was observed after 30 days.

TABLE 1

| | | H₂O | 30 wt. % H₂O₂ | H₂O:Sn | H₂O₂:Sn | |
|---|---|---|---|---|---|---|
| Sample | Precursor | spike vol. | (aq) Spike vol | mole | mole | Ppt. |
| Name: | Solution | (μL) | (μL) | ratio | ratio | observed? |
| A1 | A | 10 | 0 | 1.3 | 0 | Y |
| A2 | | 60 | 0 | 7.6 | 0 | Y |
| A3 | | 100 | 0 | 12.7 | 0 | Y |
| A4 | | 0 | 10 | 0.9 | 0.22 | Y |
| A5 | | 0 | 60 | 5.3 | 1.32 | sl. |
| A6 | | 0 | 100 | 8.8 | 2.2 | N |
| B1 | B | 10 | 0 | 1.1 | 0 | N |
| B2 | | 60 | 0 | 6.7 | 0 | sl. |
| B3 | | 100 | 0 | 11.1 | 0 | sl. |
| B4 | | 0 | 10 | 0.8 | 0.19 | N |
| B5 | | 0 | 60 | 4.7 | 1.16 | N |
| B6 | | 0 | 100 | 7.8 | 1.94 | N |

Samples A1-A3 and B1-B3 were prepared with added water but without added H₂O₂. All but Sample B1, having 10 μL water and a blend of two precursors, yielded observable precipitates after 30 days. Samples A4-A6 and B4-B6 were prepared without added water but with added H₂O₂. Samples A4-A6, having 10 μL, 60 μL, and 100 μL of the H₂O₂ additive solution, respectively, showed a decrease in the amount of observed precipitation from “Y” to “sl.” to “N”. As the peroxide concentration increased, the amount of observed precipitation for Samples A4-A6 decreased even as the mole ratio of H₂O to Sn increased (from 0.9 to 8.8). Blended precursor Samples B4-B6 yielded no observable precipitation.

Notably, the results show that the stability of the precursor solution having a single organotin precursor composition (Precursor Solution A) can be improved by the addition of a peroxide compound. For example, Sample A6, prepared with 100 μL of the peroxide additive, was not observed to form precipitates despite containing a higher water to tin mole ratio (H₂O:Sn=8.8) than Sample A2 (H₂O:Sn=7.6). Based on past experience, at low enough water levels, Precursor Solution A is stable against precipitation without peroxide, but controlling water levels to such low levels is not desirable commercially. Similar behavior is observed for the samples comprising a blend of two different organotin precursor compositions. For example, Sample B6 was not observed to form precipitates despite containing a higher water to tin mole ratio (H₂O:Sn=7.8) than Sample B2 (H₂O:Sn=6.7). Sample B2 was observed to form a slight amount of observable precipitates at a lower water concentration than Sample B6. The results suggest that the addition of a peroxide compound to an organotin precursor solution can improve the stability of the solution with respect to the formation of precipitates. Furthermore, the stabilizing effect of the peroxide compound seems to aid in the stability of precursor solutions having added water. Additionally, the results suggest that blending of precursors in a precursor solution may provide a further stabilizing effect.

These results demonstrated that peroxide additives can improve the hydrolytic stability against precipitation of organotin photoresist precursor solutions.

### Example 2: Improved EUV Sensitivity of Peroxide-Enhanced Organotin Photoresist Coatings Prepared with Hydrogen Peroxide Additive

This example demonstrates improved sensitivity to EUV radiation for organotin photoresist coatings formed from precursor solutions comprising an aqueous hydrogen peroxide solution as an additive composition.

Two peroxide-stabilized organotin photoresist precursor solutions were prepared. Resist Precursor Solution A (SA) was prepared by adding and mixing 30 wt. % H₂O₂(aq) into a 0.05 M [Sn] solution of tBuSn(OtAmyl)₃ in 4-methyl-2-pentanol to form a final solution having a 2.1 H₂O₂:1 Sn molar ratio (i.e., 4500 ppm H₂O₂). Resist Precursor Solution B (SB) was prepared by adding and mixing 30 wt. % H₂O₂(aq) into a 0.05 M [Sn] solution of mixture of tBuSn(OtAmyl)₃ and MeSn(OtAmyl)₃ in a 4:1 molar ratio in 4-methyl-2-pentanol to form a final solution having a 2.1 H₂O₂:1 Sn molar ratio (i.e., 4500 ppm H₂O₂). The solvent for both solutions was adjusted 300 ppm water. No precipitation was observed for either sample after 5 days.

For comparison, two organotin photoresist precursor solutions were prepared without peroxide. Comparative Resist Precursor Solution 1 (CS1) was prepared by adding and mixing tBuSn(OtAmyl)₃ in 4-methyl-2-pentanol to form a 0.044 M [Sn] solution. CS1 provides a precursor solution without added peroxide for comparison to precursor solution SA. Comparative Resist Precursor Solution 2 (CS2) was prepared by adding and mixing a mixture of tBuSn(OtAmyl)₃ and MeSn(OtAmyl)₃ in a 4:1 molar ratio in 4-methyl-2-pentanol to form a 0.05 M [Sn] solution. CS2 provides a precursor solution without added peroxide for comparison to precursor solution SB. No precipitation was observed for either sample after 5 days.

Each resist precursor solution was spin-coated onto silicon wafers coated with an approximately 10 nm thick layer of spin-on-glass (SOG) to yield organotin photoresist films with thicknesses of approximately 22 nm. Each wafer was then subjected to a post-apply bake (PAB) at 100° C. for 60 seconds. Contrast arrays were then produced for each wafer by exposing an array of pads having EUV doses of 2 mJ/cm² to 90 mJ/cm² using an ASML TwinScan NXE3400 EUV exposure tool. Following EUV irradiation, the wafers were then subjected to a post-exposure bake (PEB) at 160° C., 170° C., or 180° C. for 60 seconds. The wafers were then developed with 2-heptanone and hard baked at 150° C. for 60 seconds. After development, the thickness of each pad was measured via ellipsometry and the results were plotted to extract dose-to-gel (Dg) values for each resist. The PEB temperature and the dose-to-gel (Dg) values for each organotin resist sample are shown in Table 2, wherein “**” indicates that Dg could not be measured.

TABLE 2

| | Resist Precursor | PEB | Dg |
|---|---|---|---|
| Resist Sample | Solution | (° C.) | (mJ/cm²) |
| Comparative Resist 1-1 | CS1 | 160 | 16.9 |
| Comparative Resist 1-2 | CS1 | 170 | 15.0 |
| Comparative Resist 1-3 | CS1 | 180 | 12.1 |
| Resist A -1 | SA | 160 | 9.8 |
| Resist A -2 | SA | 170 | 5.6 |
| Resist A -3 | SA | 180 | ** |
| Comparative Resist 2-1 | CS2 | 160 | 14.4 |
| Comparative Resist 2-2 | CS2 | 170 | 12.9 |
| Comparative Resist 2-3 | CS2 | 180 | 10.5 |
| Resist B-1 | SB | 160 | 4.2 |
| Resist B-2 | SB | 170 | 2.4 |
| Resist B-3 | SB | 180 | ** |

As shown in Table 2, the peroxide-enhanced organotin resist coatings (Resists A-1 to A-3 and B-1 to B-3) exhibited much lower dose-to-gel values than the non-peroxide-enhanced organotin resist coatings (Comparative Resists 1-1 to 1-3 and 2-1 to 2-3). Though Comparative Resists 1-1 to 1-3 and Resists A-1 to A-3 were prepared from identical organotin precursors, the Resist A series, prepared with a precursor solution having a peroxide additive, showed a significantly lower Dg at each PEB condition compared to the Comparative Resist 1 series. For example, the dose-to-gel values for Resists A-1 (160° C. PEB) and A-2 (170° C. PEB) were 9.8 mJ/cm² and 5.6 mJ/cm², respectively, while the dose-to-gel values for Comparative Resists 1-1 (160° C. PEB) and 1-2 (170° C. PEB) were 16.9 mJ/cm² and 15.0 mJ/cm², respectively. Furthermore, the decrease in the dose-to-gel values with the increase in PEB temperature from 160° C. to 170° C. was 43% for the Resist A series samples and only 110% for the Comparative Resist series samples. After a 180° C. PEB, Resist A-3 exhibited significant EUV sensitivity such that Dg could not be extracted.

Similar results are seen when comparing Comparative Resists 2-1 to 2-3 and Resists B-1 to B-3, which are prepared from identical organotin precursors. The Resist B series, prepared with a precursor solution having a peroxide additive, showed significantly lower Dg values at each PEB condition compared to the Comparative Resist 2 series. For example, the dose-to-gel values for Resists B-1 (160° C. PEB) and B-2 (170° C. PEB) were 4.2 mJ/cm² and 2.4 mJ/cm², respectively, while the dose-to-gel values for Comparative Resists 2-1 (160° C. PEB) and 2-2 (170° C. PEB) were 14.4 mJ/cm² and 12.9 mJ/cm², respectively. The decrease in the dose-to-gel values with the increase in PEB temperature from 160° C. to 170° C. was 43% for the Resist B series samples and only 10% for the Comparative Resist series samples. After a 180° C. PEB, Resist B-3 exhibited significant EUV sensitivity and Dg could not be extracted. The significant EUV sensitivity of the peroxide-stabilized organotin coatings at a 180° C. PEB (Resist A-3 and Resist B-3) seem to suggest a loss of solubility contrast at elevated PEB temperatures due to significant thermal decomposition of the peroxide ligands and corresponding Sn—C cleavage in the unexposed areas.

This example demonstrated that organotin photoresist coatings prepared with precursor solutions having peroxide additive have improved sensitivity to EUV radiation and a reduction in required patterning doses as compared to organotin photoresist coatings prepared with precursor solutions without peroxide additives. The results further demonstrate that the peroxide additives enhance the sensitivity of the organotin photoresist coatings to PEB temperature, suggesting that the peroxide enhanced coatings may have reduced thermal stability.

### Example 3: Improved EUV Sensitivity of Peroxide-Enhanced Organotin Photoresist Coatings Prepared with Urea Hydrogen Peroxide Additive

This example demonstrates improved sensitivity to EUV radiation for organotin photoresist coatings formed from precursor solutions comprising a dissolved urea-hydrogen peroxide composition as an additive.

In an inert environment, a bulk solution of organotin photoresist precursor was prepared by first forming a solvent mixture of 62% 1-pentanol by weight and 38% 1-propanol by weight. An appropriate amount of organotin composition comprising 60% isopropyl tin tris(sec-butoxide) by mole and 40% tert-butyl tin tris(3-pentoxide) by mole was then combined with the solvent mixture to form an organotin precursor solution having a tin concentration of 0.065 M. An appropriate amount of water was added to the precursor solution, such that the final precursor solution had a water concentration of 300 parts per million (ppm). The bulk precursor solution was then divided into two aliquots, one of which was reserved as a comparative organotin precursor solution, absent an added peroxide compound (Precursor Solution E). Solid urea-hydrogen peroxide was added to the other aliquot at a concentration of 0.0065 M to form a peroxide-stabilized organotin precursor solution (Precursor Solution F).

The comparative precursor solution and the peroxide-stabilized precursor solution were both used to individually coat three 300 mm diameter silicon wafers (with a spin-on-glass underlayer) to form a total of six coated wafers. The coating was accomplished via spin coating at a speed from about 1100 revolutions per minute (rpm) to about 1250 rpm to form coated wafers having 30 nm thick films, as confirmed by ellipsometry. The coated wafers were then subjected to a 60 second post-application bake (PAB) at a temperature of 130° C. Then, line-space patterns having a target critical dimension (CD) of 14 nm on a 28 nm pitch (14p28) were produced for each organotin coating composition by exposing the coated wafers to 13.5 nm EUV radiation between about 0 mJ/cm² to about 100 mJ/cm² using an ASML NXE3400B exposure tool to form patterned, coated wafers having an array of patterns within fields, wherein each field corresponds to the mask pattern printed at a specified dose. As is customary in the art, this type of exposure is referred to as a dose meander exposure. By exposing the same 14p28 pattern at different doses across each coated wafer, the dose required for printing the desired 14p28 pattern for a given organotin coating composition (i.e., the dose-to-size for printing 14 nm lines on a 28 nm pitch) can be determined through inspection of each field of the patterned, coated wafer after processing is complete. The irradiated, coated wafers were then subjected to a 60 second post-exposure bake (PEB) at a temperature of 200° C., 210° C., or 220° C. to form baked, irradiated wafers.

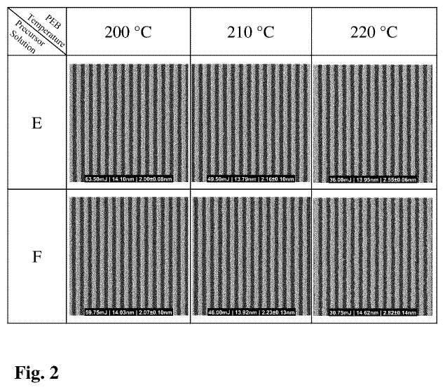

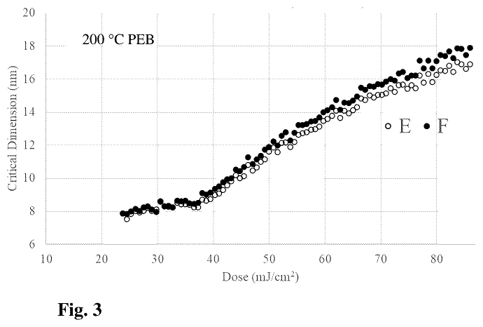

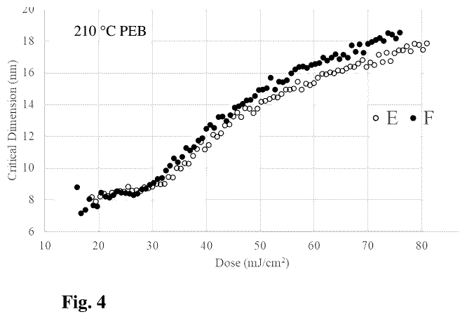

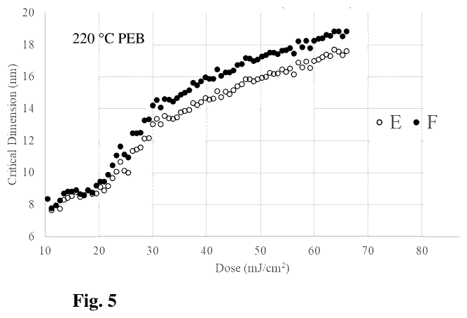

The baked, patterned wafers were then developed with HBr plasma in a etch reactor from TEL in a negative tone development process to form developed wafers. The developed wafers were inspected using a Hitachi CD-SEM to determine the critical dimension of line-space pattern in each field of the developed wafer. The EUV dose and resulting critical dimension values for the wafers exposed to a 200° C., 210° C., or 220° C. PEB are presented in FIGS. 3-5, respectively. The dose-to-size corresponding to the critical dimension nearest to 14 nm and resulting line width roughness are presented in Table 3. The CD-SEM images analyzed using metrology to determine these values are presented in FIG. 2.

TABLE 3

| | PEB | | Critical | Line Width |
|---|---|---|---|---|
| Precursor | Temperature | Dose | Dimension | Roughness |
| Solution | (° C.) | (mJ/cm²) | (nm) | (nm) |
| E | 200 | 63.50 | 14.10 | 2.00 ± 0.08 |
| E | 210 | 49.50 | 13.79 | 2.16 ± 0.10 |
| E | 220 | 36.00 | 13.95 | 2.55 ± 0.06 |
| F | 200 | 59.75 | 14.03 | 2.07 ± 0.10 |
| F | 210 | 46.00 | 13.92 | 2.23 ± 0.13 |
| F | 220 | 30.75 | 14.62 | 2.82 ± 0.14 |

As shown in Table 3 and FIGS. 3-5, the addition of urea hydrogen peroxide to the precursor solution reduced the dose necessary to produce a desired critical dimension line-space pattern on coatings formed therefrom over a range of PEB temperatures. Coatings formed from Precursor Solution F, comprising a urea hydrogen peroxide additive, corresponded to a lower dose-to-size for 14 nm line-space patterns than the coatings formed from the comparative non-peroxide precursor solution, Precursor Solution E, at all PEB temperatures tested. The dose-to-size reductions realized from the addition of the urea-hydrogen peroxide additive were measured to be 3.75 mJ/cm², 3.50 mJ/cm², and 5.25 mJ/cm² for PEB temperatures of 200° C., 210° C., and 220° C., respectively. The addition of the urea-hydrogen peroxide compound increased the line width roughness (LWR) by 0.07 nm, 0.07 nm, and 0.27 nm for PEB temperatures of 200° C., 210° C., and 220° C., respectively.

This example demonstrates that the dissolution of solid urea hydrogen peroxide additive into an organotin precursor solution can increase the EUV sensitivity of coatings formed therefrom. Peroxide-enhanced organotin coatings, formed from peroxide-stabilized organotin precursors, showed a lower necessitated EUV dose required to achieve a desired critical dimension line-space pattern than comparative non-peroxide enhanced coatings. The LWR increase accompanying the increased sensitivity is relatively low, indicating that the dissolution of peroxide compounds into organotin precursor solutions can enable dose reductions without significantly compromising patterning performance.

### Example 4: Synthesis of O,O-bis ethylphenyl peroxydisulfate

This example describes a method for the direct synthesis and purification of O,O-bis ethylphenyl peroxydisulfate, (C₈H₉)₂S₂O₈, represented by Formula 1. The synthesis is based on the following double displacement reaction:

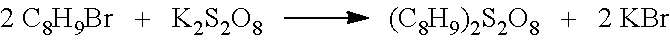

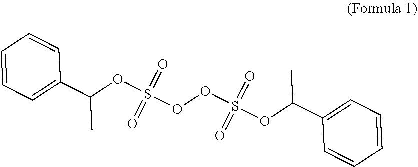 [SMILES: CC(OS(=O)(=O)OOS(=O)(=O)OC(C)c1ccccc1)c1ccccc1]

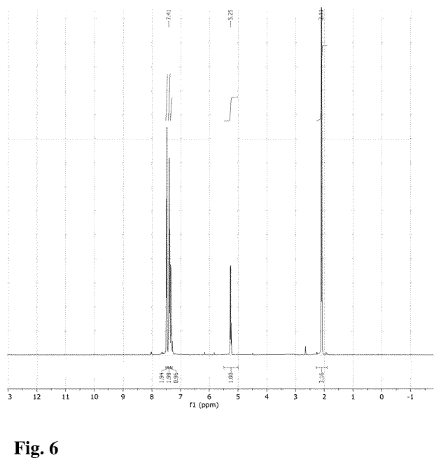

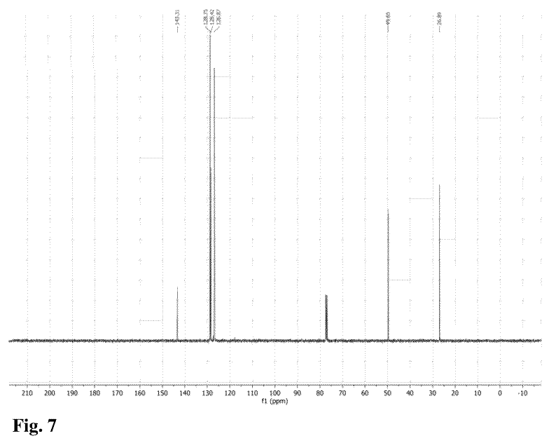

First, 16 mmol of 1-Bromoethylbenzene (C₈H₉Br) was combined with 8 mmol of potassium persulfate (K₂S₂O₈). The potassium persulfate was not soluble in the 1-Bromoethylbenzene, but was consumed as the reaction mixture was continuously stirred and progressed at room temperature for 2 hours. The reacted mixture was then filtered to remove solid potassium bromide salt (KBr) and subsequently dried under vacuum to afford the title compound as a liquid at a yield of approximately 70%. Proton nuclear magnetic resonance (¹H NMR) spectroscopy was performed in CDCl₃ at 400 MHz to characterize the product and showed the following chemical shifts: δ 2.10 (3H, d), 5.25 (1H, dd), 7.28-7.51 (5H, m). Furthermore, carbon NMR (¹³C NMR) was performed in CDCl₃ at 100 MHz to characterize the product and showed the following chemical shifts: δ 26.89 (CH3), 49.65.33 (CH), 126.87(CH-AR), 128.42(CH-AR), 128.75(CH-AR), 143.31(CH-AR), wherein AR is an aromatic group. The ¹H and ¹³C NMR spectra for the synthesized product are shown in FIGS. 6 and 7, respectively.

### Example 5: Improved EUV Sensitivity of Peroxide-Enhanced Organotin Photoresist Coatings Prepared with a Bis-Organo Peroxydisulfate Additive

This example demonstrates improved sensitivity to EUV radiation for organotin photoresist coatings formed from precursor solutions comprising a O,O-bis(ethylphenyl)peroxydisulfate composition as an additive.

In an inert environment, a bulk solution of organotin photoresist precursor was prepared by first forming a solvent mixture of 62% 1-pentanol by weight and 38% 1-propanol by weight. An appropriate amount of organotin composition comprising 60% isopropyl tin tris(sec-butoxide) by mole and 40% tert-butyl tin tris(3-pentoxide) by mole was then combined with the solvent mixture to form an organotin precursor solution having a tin concentration of 0.065 M. An appropriate amount of water was added to the precursor solution, such that the final precursor solution had a water concentration of 300 parts per million (ppm). The bulk precursor solution was then divided into two aliquots, one of which was reserved as a comparative organotin precursor solution, absent a peroxide compound (Precursor Solution G). Neat liquid O,O-bis phenylethyl peroxydisulfate was combined with the other aliquot at a concentration of 0.0065 M to form a peroxide-stabilized organotin precursor solution (Precursor Solution H).

The comparative precursor solution and peroxide-stabilized precursor solution were both used to individually coat three 300 mm diameter silicon wafers with a spin-on-glass underlayer to form a total of six coated wafers. The coating was accomplished via spin coating at a speed from about 1300 revolutions per minute (rpm) to about 1500 rpm to form a 30 nm thick coating, confirmed by ellipsometry. The coated wafers were then subjected to a 60 second post-application bake (PAB) at a temperature of 130° C. Then, line-space patterns having a target critical dimension (CD) of 14 nm on a 28 nm pitch (14p28) were produced for each organotin coated wafer by exposing the coated wafers to 13.5 nm EUV radiation between about 8.75 mJ/cm² to about 100 mJ/cm² using an ASML NXE3400B exposure tool to form irradiated, coated wafers having an array of patterns within fields, wherein each field corresponds to the mask pattern printed at a specified dose. As is customary in the art, this type of exposure is referred to as a dose meander exposure. By exposing the same 14p28 pattern at different doses across each coated wafer, the dose required for printing the desired 14p28 pattern for a given organotin coating composition (i.e., the dose-to-size for printing 14 nm lines on a 28 nm pitch) can be determined through inspection of each field of the patterned, coated wafer after processing is complete. The irradiated, coated wafers were then subjected to a 60 second post-exposure bake (PEB) at a temperature of 200° C., 210° C., or 220° C. to form baked, irradiated wafers.

The baked, irradiated wafers were then developed using HBr plasma in a TEL Tactras™ etch platform in a negative tone development process to form developed wafers. The developed wafers were inspected using a Hitachi CD-SEM to determine the critical dimension of line-space pattern in each field of the developed wafer. The dose-to-size corresponding to the critical dimension nearest to 14 nm are presented in Table 4, with ‘**’ indicating that a critical dimension of 14 nm was not achieved in range of meander doses tested.

TABLE 4
Temperature Critical Dimension Dose to Size (mJ/cm2)

| Precursor | PEB Temperature | Critical | |
|---|---|---|---|
| Solution | (° C.) | Dimension (nm) | Dose to Size (mJ/cm²) |
| G | 200 | 13.94 | 59.75 |
| G | 210 | 14.13 | 51.00 |
| G | 220 | 13.99 | 38.75 |
| H | 200 | 13.98 | 23.75 |
| H | 210 | 14.04 | 14.5 |
| H | 220 | ** | ** |

As shown in Table 4, the addition of O,O-bis(ethylphenyl) peroxydisulfate to the precursor solution reduced the dose necessary to produce a line-space pattern having a critical dimension of 14 nm. This effect was observed for PEB temperatures of 200° C., 210° C., and 220° C. Coatings formed from precursor solution H, comprising an O,O-bis(ethylphenyl) peroxydisulfate additive, corresponded to a lower dose-to-size for 14 nm line-space patterns than the coatings formed from the comparative non-peroxide precursor solution, G, at all PEB temperatures tested. The dose-to-size reductions realized from the addition of O,O-bis(ethylphenyl) peroxydisulfate additive were measured to be 36 mJ/cm² and 36.5 mJ/cm² at PEB temperatures of 200° C. and 210° C., respectively.

This example demonstrates that the addition of a O,O-bis(ethylphenyl) peroxydisulfate additive to an organotin precursor solution can increase the EUV sensitivity of coatings formed therefrom. Peroxide-enhanced organotin coatings formed from peroxide-stabilized organotin precursors show a lower necessitated EUV dose required to achieve a 14p28 line-space pattern than a comparative non-peroxide enhanced coating.

### Further Inventive Concepts:

B. A coated substrate comprising a substrate with a surface and a layer on the surface comprising organo tin moieties, an oxo-hydroxo network, and a peroxide composition.
B1. The coated substrate of inventive concept B wherein the layer is radiation sensitive.
B2. The coated substrate of inventive concept B wherein the layer comprises Sn—C bonds and wherein the Sn—C bonds are radiation sensitive.
B3. The coated substrate of any one of inventive concepts B-B2 wherein the layer comprises Sn—O—Sn, Sn—OH, Sn—C, and O—O bonds.
B4. The coated substrate of inventive concept B3 wherein the Sn—C bonds can be cleaved by at least one of EUV, UV, and e-beam radiation.
B5. The coated substrate of any one of inventive concepts B-B4 wherein the peroxide composition comprises ligands bonded to tin.
B6. The coated substrate of inventive concept B5 wherein the peroxide ligands bound to tin are radiation sensitive.
B7. The coated substrate of any one of inventive concepts B-B6 wherein the peroxide composition comprises a hydrogen peroxide, urea hydrogen peroxide, O,O-bis ethylphenyl peroxydisulfate, a composition having a peroxydisulfate group, or a combination thereof.
B8. The coated substrate of any one of inventive concepts B-B7 wherein the layer comprises the peroxide composition and the organo tin moieties in a molar ratio from about 0.00005 to about 2.5.
B9. The coated substrate of any one of inventive concepts B-B8 wherein the substrate comprises a silicon wafer.
B10. The coated substrate of any one of inventive concepts B-B9 wherein the layer has an average thickness from about 1 nm to about 50 nm.
B11. The coated substrate of any one of inventive concepts B-B10 wherein the layer is formed by depositing the organotin precursor solution according to any one of claims 1-22 onto the substrate.
B12. The coated substrate of inventive concept B11 wherein the depositing is by a spin-coating, spray coating, dip coating, knife edge coating, or printing process or combinations thereof.
C. A patterned substrate comprising a substrate with a patterned layer with an unirradiated region comprising organo tin moieties, an oxo-hydroxo network and a peroxide composition, and an irradiated region having an enhanced oxo-hydroxo network with at least some tin atoms fragmented from organo groups and at least some peroxide composition not persisting.
C1. The patterned substrate of inventive concept C wherein the unirradiated region has a molar ratio of the peroxide composition to the organo tin moieties from about 0.00005 to about 2.5.
C2. The patterned substrate of inventive concept C or inventive concept C1 wherein the peroxide composition comprises ligands bonded to tin, wherein the peroxide ligand-tin bond is radiation sensitive.
C3 The patterned substrate of any one of inventive concepts C-C2 wherein the peroxide composition comprises hydrogen peroxide, urea hydrogen peroxide, O,O-bis ethylphenyl peroxydisulfate, a composition having a peroxydisulfate group, or a combination thereof.
C4. The patterned substrate of any one of inventive concepts C-C2 wherein the peroxide composition is hydrogen peroxide.
C5. The patterned substrate of any one of inventive concepts C-C2 wherein the peroxide composition comprises a sulfate group.
C6. The patterned substrate of any one of inventive concepts C-C2 wherein the peroxide composition comprises a benzyl group and a sulfate group.
C7. The patterned substrate of any one of inventive concepts C-C6 wherein the unirradiated region is soluble in at least some organic solvents and the irradiated region is not soluble in the organic solvents.
C8. The patterned substrate of any one of inventive concepts C-C7 wherein the irradiated region is soluble in aqueous acids and/or aqueous bases.
C9. The patterned substrate of any one of inventive concepts C-C8 wherein the substrate comprises a silicon wafer.
C10. The patterned substrate of any one of inventive concepts C-C9 wherein the irradiated region has a reduced organic content.
C11. The patterned substrate of inventive concept C10 wherein the fragmented organo groups result in a volatile compound.
D. A method for forming the patterned substrate of any one of inventive concepts C-C11 comprising irradiating the coated substrate of any one of inventive concepts B-B12 with patterned radiation.
D1. The method of inventive concept D wherein the patterned radiation comprises EUV, UV, or e-beam radiation.
D2. The method of inventive concept D wherein the patterned radiation comprises EUV radiation.
E. An organo peroxydisulfate represented by the formula:

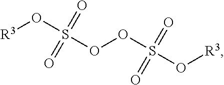

where R³ is an organo group with 1 to 15 carbon atoms, with optional unsaturated groups, optional aromatic groups, and combinations thereof.
E1. The organo peroxydisulfate of inventive concept E wherein R³ is a linear, cyclic, or branched alkyl group having from about 1 to about 15 carbon atoms or an aryl group having from about 1 to about 15 carbon atoms.
E2. The organo peroxydisulfate of inventive concept E wherein R³ is an ethylphenyl group and the organo peroxydisulfate is represented by the formula:

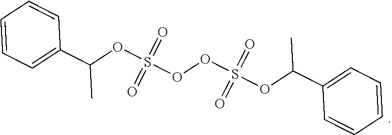 [SMILES: CC(OS(=O)(=O)OOS(=O)(=O)OC(C)c1ccccc1)c1ccccc1]

E3. The organo peroxydisulfate of inventive concept E wherein R³ is a tert-butyl group and the organo peroxydisulfate is represented by the formula:

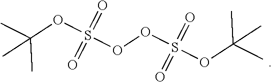 [SMILES: CC(C)(C)OS(=O)(=O)OOS(=O)(=O)OC(C)(C)C]

E4. The organo peroxydisulfate of any one of inventive concepts E-E3 wherein the organo peroxydisulfate is a liquid at room temperature.
F. A method for synthesizing an organo peroxydisulfate comprising
reacting a mixture of an organohalide, R³X, and a peroxydisulfate anion,
wherein R³ is an organo group with 1 to 15 carbon atoms, with optional unsaturated groups, optional aromatic groups, or a combination thereof, and X is a halogen.
   F1. The method of inventive concept F wherein the mixture comprises the organohalide and the peroxydisulfate anion is a molar ratio of about 0.25:1 to about 4:1.
   F2. The method of inventive concept F or claim F1 wherein R³ is an ethyl phenyl group or a t-butyl group.
   F3. The method of any one of inventive concepts F-F2 wherein X is Br.
   F4. The method of any one of inventive concepts F-F3 wherein the peroxydisulfate anion is provided by a peroxydisulfate salt, M₂S₂O₈, wherein M is an alkali metal or ammonium (NH₄⁺).
   F5. The method of any one of inventive concepts F-F3 wherein the mixture comprises potassium peroxydisulfate.
   F6. The method of any one of inventive concepts F-F5 wherein the reacting is performed at room temperature.
   F7. The method of any one of inventive concepts F-F6 wherein the reacting is performed for a period of time from about 0.1 minute to about 1 day.
   F8. The method of any one of inventive concepts F-F7 further comprising stirring during the reacting step.
   F9. The method of any one of inventive concepts F-F8 further comprising filtering after the reacting step to form a filtered product.
   F10. The method of inventive concept F9 further comprising vacuum drying the filtered product.

In the above disclosure, it should be understood that certain terms are used interchangeably with each other. For example, one of ordinary skill in the art will understand that the terms “coating”, “layer”, and “film” are meant to construe the same idea, unless explicitly stated otherwise.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understood that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. As would be understood by a person of ordinary skill in the art, the use of the term “about” herein refers to measurement error for the particular parameter unless explicitly indicated otherwise.

What is claimed is:

1. An organotin precursor solution comprising a mixture of:
an organic solvent,
a first organotin composition represented by the formula RₙSnX₄₋ₙ where n=1, 2 or 3, R is an organo group with 1 to 31 carbon atoms and X is a hydrolysable ligand, and
a peroxide composition.

2. The precursor solution of claim 1 having a Sn concentration from about 0.0025 M to about 1.0 M.

3. The precursor solution of claim 1 wherein the peroxide composition comprises an inorganic peroxide.

4. The precursor solution of claim 1 wherein the peroxide composition comprises an organic peroxide.

5. The precursor solution of claim 1 wherein the peroxide composition comprises a hydroperoxide, a composition having a peroxydisulfate group, or a combination thereof.

6. The precursor solution of claim 1 wherein the peroxide composition comprises O,O-bis ethylphenyl peroxydisulfate.

7. The precursor solution of claim 1 wherein the mixture comprises the peroxide composition and the organotin composition in a molar ratio from about 0.005 to about 2.

8. The precursor solution of claim 1 wherein the mixture comprises the peroxide composition and the first organotin composition in a molar ratio from about 0.00005 to about 2.5.

9. The precursor solution of claim 7 wherein the peroxide composition comprises hydrogen peroxide or urea hydrogen peroxide.

10. The precursor solution of claim 1 wherein X is a dialkylamide, an alkylsilylamide, an alkoxide, an alkylacetylide, or a combination thereof.

11. The precursor solution of claim 1 wherein X is an alkoxide.

12. The precursor solution of claim 1 wherein n=1.

13. The precursor solution of claim 1 wherein the first organotin composition comprises isopropyl tin tris(sec-butoxide), tert-butyl tin tris(3-pentoxide), tBuSn(OtAmyl)₃, or MeSn(OtAmyl)₃, or a combination thereof.

14. The precursor solution of claim 1 wherein the organo group comprises a cyano, thio, silyl, ether, keto, ester, a halogenated functional group or a combination thereof.

15. The precursor solution of claim 1 wherein the mixture further comprises a second organotin composition represented by the formula R′ₙSnX′₄₋ₙ where n=1, 2 or 3, R′ is an organo group with 1 to 31 carbon atoms and X′ is a hydrolysable ligand, and wherein the first organotin composition and the second organotin composition are different.

16. The precursor solution of claim 15 wherein the second organotin composition comprises at least about 5 mol percent of the organotin moles.

17. The precursor solution of claim 15 wherein the mixture comprises the peroxide composition and a sum of the first organotin composition and the second organotin composition in a molar ratio from about 0.00005 to about 2.5.

18. The precursor solution of claim 1 wherein the organic solvent comprises an alcohol, an alkane, an aromatic hydrocarbon, an ether, an ester, a ketone, or combination thereof.

19. The precursor solution of claim 1 wherein the organic solvent comprises an alcohol or a mixture of alcohols.

20. The precursor solution of claim 1 wherein the organic solvent comprises one or more of methanol, ethanol, propanol, butanol, pentanol, hexanol, heptanol, octanol, nonanol, decanol, and branched versions thereof.

21. The precursor solution of claim 1 wherein the organic solvent comprises 4-methyl-2-pentanol.

22. The precursor solution of claim 1 wherein the precursor solution comprises water at a concentration from 200 to 10,000 ppm.

23. An article comprising a container and, within the container, the precursor solution of claim 1, wherein the container is sealed from the ambient atmosphere.

24. The article of claim 23 further comprising, within the container, an inert atmosphere.

25. The article of claim 23 wherein the precursor solution has no observable precipitation for at least 30 days.

26. A method of preparing an organotin precursor solution, the method comprising:
combining an organic solvent, a peroxide composition and a first organo tin composition represented by the formula RₙSnX₄₋ₙ, where n=1, 2 or 3, R is an organo group with 1 to 31 carbon atoms and X is a hydrolysable ligand.

27. The method of claim 26 wherein the first organotin composition and the organic solvent are mixed to form a mixture, and the peroxide composition is added to the mixture.

28. The method of claim 26 wherein the peroxide composition comprises an aqueous peroxide solution.

29. The method of claim 26 wherein the peroxide composition comprises an aqueous hydrogen peroxide solution having from 0.1 to 35% H₂O₂ by weight.

30. The method of claim 26 wherein the peroxide composition comprises a solid.

31. The method of claim 26 wherein the peroxide composition is urea hydrogen peroxide.

32. The method of claim 26 wherein X is a dialkylamide, an alkylsilylamide, an alkoxide, an alkylacetylide, or a combination thereof.

33. The method of claim 26 wherein X is an alkoxide.

34. The method of claim 26 wherein n=1.

35. The method of claim 26 wherein the first organotin composition comprises isopropyl tin tris(sec-butoxide), tert-butyl tin tris(3-pentoxide), tBuSn(OtAmyl)₃, or MeSn(OtAmyl)₃, or a combination thereof.

36. The method of claim 26 wherein the organo group comprises a cyano, thio, silyl, ether, keto, ester, a halogenated functional group or a combination thereof.

37. The method of claim 26 wherein the combining further comprises a second organotin composition represented by the formula R′ₙSnX′₄₋ₙ where n=1, 2 or 3, R′ is an organo group with 1 to 31 carbon atoms and X′ is a hydrolysable ligand, and wherein the first organotin composition and the second organotin composition are different.

38. The method of claim 37 wherein the second organotin composition comprises at least about 5 mol percent of the organotin moles.

39. The method of claim 37 wherein the organotin precursor solution has the peroxide composition and a sum of the first organotin composition and the second organotin composition in a molar ratio from about 0.00005 to about 2.5.

40. The method of claim 26 wherein the combining is performed in an inert environment.

41. The method of claim 40 wherein the inert environment consists essentially of nitrogen, a noble gas, or a combination thereof.

42. The method of claim 26 wherein the combining is performed at room temperature.

43. The method of claim 26 further comprising stirring during and/or after the combining step.

44. The method of claim 26 wherein the organotin precursor solution has water in a molar ratio of water to Sn from about 0.1 to about 20, wherein water is added to the organic solvent, to the peroxide composition, to the combined ingredients, or a combination thereof.

45. The method of claim 26 further comprising introducing an amount of water, wherein after the combining and adding steps the precursor solution has a selected concentration of water from about 200 ppm to about 10,000 ppm.

46. The method of claim 26 further comprising transferring the precursor solution into a container and sealing the container from the ambient atmosphere.
